(19) United States
(12) Patent Application Publication
(10) Pub. No.: US 2026/0206388 A1
(43) Pub. Date: Jul. 16, 2026

(54) ORGANIC FILM COMPOSITION FOR ADHESION, DISPLAY DEVICE INCLUDING THE SAME, AND ELECTRONIC DEVICE INCLUDING THE SAME

(71) Applicant: Samsung Display Co., Ltd., Yongin-si (KR)

(72) Inventors: Ah Sell CHO, Yongin-si (KR); Hwa Jeong CHOI, Yongin-si (KR); Gi Suk KWON, Yongin-si (KR); Woong KIM, Yongin-si (KR); Ki Cheol SONG, Yongin-si (KR)

(21) Appl. No.: 19/381,767

(22) Filed: Nov. 6, 2025

(30) Foreign Application Priority Data
Jan. 14, 2025 (KR) 10-2025-0005228

(51) Int. Cl. H10H 29/41; C09J 4/06; C09J 7/38; H10H 20/84

(52) U.S. Cl. CPC H10H 29/41; C09J 4/06; C09J 7/385; H10H 20/84; C09J 2203/326; C09J 2301/414; C09J 2301/416

(57) ABSTRACT

An organic film composition for adhesion, a display device including an organic film, and an electronic device including an organic film are disclosed. The organic film composition for adhesion may include: a monomer represented by Chemical Formula 1; a reactive unsaturated compound represented by Chemical Formula 2; a photoinitiator; and a solvent, wherein the organic film composition for adhesion includes: 25 parts to 50 parts by weight of the monomer represented by Chemical Formula 1; 5 parts to 10 parts by weight of the reactive unsaturated compound represented by Chemical Formula 2; 0.25 parts to 5 parts by weight of the photoinitiator; and 40 parts to 70 parts by weight of the solvent, with respect to (e.g., based on) 100 parts by weight of the organic film composition for adhesion.

### CROSS-REFERENCE TO RELATED APPLICATION

The present application claims priority to and the benefit of Korean Patent Application No. 10-2025-0005228, filed on Jan. 14, 2025, in the Korean Intellectual Property Office, the entire disclosure of which is incorporated herein by reference.

### BACKGROUND

### 1. Field

One or more embodiments of the present disclosure relate to an organic film composition for adhesion, a display device including an organic film, and an electronic device including the organic film.

### 2. Description of the Related Art

With the advance of information-oriented society, it is desirable to develop display devices to display images in one or more suitable ways. The display devices may be a flat panel display device, such as a liquid crystal display, a field emission display, and a light emitting display.

The light emitting displays may include an organic light emitting display including an organic light emitting diode element as a light emitting element and an ultra-small light emitting display including an ultra-small light emitting diode element (hereinafter, referred to as a micro light emitting diode element) as a light emitting element. The ultra-small light emitting diode element is made of an inorganic material and has lower degradation issues compared to an organic light emitting diode element and thus has the advantage or benefit of a longer lifespan.

Because a plurality of light emitting elements are formed or provided on separate substrates, a process to transfer them to a display panel is required or desired. However, in the case of transferring the plurality of light emitting elements to the display panel, the plurality of light emitting elements may tilt without being fixed or may fall.

### SUMMARY

One or more aspects of embodiments of the present disclosure are directed toward an organic film (e.g., an organic film composition for adhesion) of which fluidity and adhesion force are improved or enhanced in order to prevent a plurality of light emitting elements from tilting and/or falling (or to reduce a degree to or occurrence of which a plurality of light emitting elements tilts and/or falls) during the process of transferring the plurality of light emitting elements to a display panel.

However, aspects and features of embodiments of the present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

Additional aspects of embodiments will be set forth in part in the description which follows and, in part, will be apparent from the description or may be learned by practice of the presented embodiments of the disclosure.

According to one or more embodiments of the present disclosure, an organic film composition for adhesion includes: a monomer represented by Chemical Formula 1; a reactive unsaturated compound represented by Chemical Formula 2; a photoinitiator; and a solvent, wherein the organic film composition for adhesion includes: 25 parts to 50 parts by weight of the monomer represented by the Chemical Formula 1; 5 parts to 10 parts by weight of the reactive unsaturated compound represented by the Chemical Formula 2; 0.25 parts to 5 parts by weight of the photoinitiator; and 40 parts to 70 parts by weight of the solvent, with respect to (e.g., based on) 100 parts by weight of the organic film composition for adhesion:

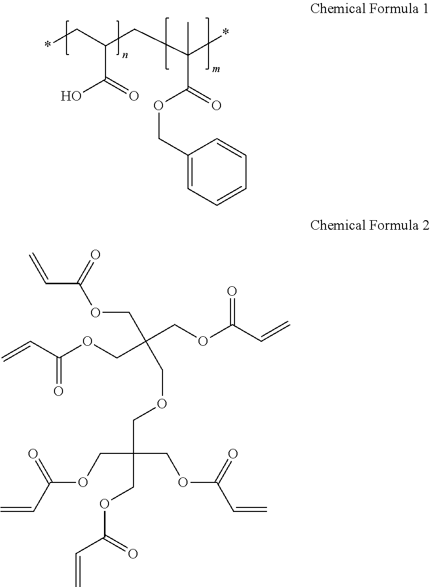

where n and m are integers.
R_{C═C/C═O} of Equation 1 may be 0.28 or more:

$${R}_{C = C / C = O} = {I}_{C = C} / {I}_{C = O} \qquad Equation 1$$

where the I_{C═C} is a C═C bond peak intensity in an infrared spectral spectrum, and the I_{C═O} is a C═O bond peak intensity in the infrared spectral spectrum.

An adhesion force of the organic film composition for adhesion may be equal to or greater than 2.2 mN.

A modulus of the organic film composition for adhesion may be equal to or less than 1.5 GPa.

A bonding rate of the organic film composition for adhesion may be 99.99% or higher at a temperature of 40° C. or higher.

According to one or more embodiments of the present disclosure, a display device includes: a substrate; an organic film on the substrate; and a light emitting element on the organic film, wherein the organic film includes a monomer represented by Chemical Formula 1; a reactive unsaturated compound; a photoinitiator; and a solvent, wherein the organic film includes: 25 parts to 50 parts by weight of the monomer represented by the Chemical Formula 1; 5 parts to 10 parts by weight of the reactive unsaturated compound; 0.25 parts to 5 parts by weight of the photoinitiator; and 40 parts to 70 parts by weight of the solvent, with respect to (e.g., based on) 100 parts by weight of the organic film:

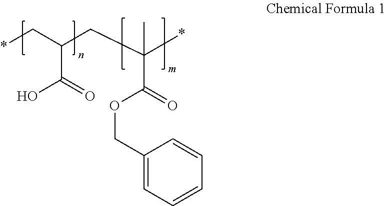

where n and m are integers.

The reactive unsaturated compound may include a compound represented by Chemical Formula 2:

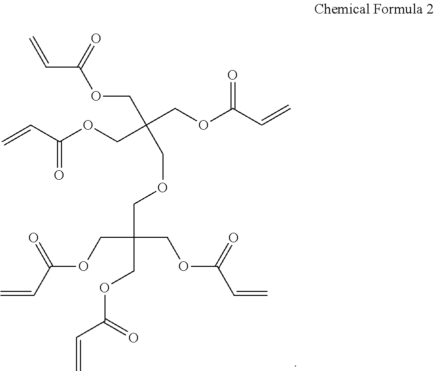 [SMILES: C=CC(=O)OCC(COCC(COC(=O)C=C)(COC(=O)C=C)COC(=O)C=C)(COC(=O)C=C)COC(=O)C=C]

R_{C═C/C═O} of Equation 1 may be 0.28 or more:

$${R}_{C = C / C = O} = {I}_{C = C} / {I}_{C = O} \qquad Equation 1$$

where the I_{C═C} is a C═C bond peak intensity in an infrared spectral spectrum, and the I_{C═O} is a C═O bond peak intensity in the infrared spectral spectrum.

An adhesion force of the organic film may be equal to or greater than 2.2 mN.

A modulus of the organic film may be equal to or less than 1.5 GPa.

A bonding rate of the organic film may be 99.99% or higher at a temperature of 40° C. or higher.

The photoinitiator may include an oxime-based photoinitiator.

The organic film may further include an ionic initiator.

The light emitting element may include: a semiconductor stack; a protective film on a side surface of the semiconductor stack; and a contact electrode on the protective film, wherein a part of the side surface of the semiconductor stack is exposed without being covered by the contact electrode, and the contact electrode is spaced and/or apart (e.g., spaced apart or separated) from a top surface of the semiconductor stack.

The light emitting element may include: a semiconductor stack; a conductive (e.g., electrically conductive) layer between the organic film and the semiconductor stack; a protective film on side surfaces of the conductive layer and side surfaces of the semiconductor stack; a first contact electrode located or provided on the protective film and connected to a conductive (e.g., electrically conductive) layer exposed without being covered by the protective film; and a second contact electrode located or provided on the protective film and located or provided in a hole penetrating the conductive layer and a part of the semiconductor stack, wherein each of the first contact electrode and the second contact electrode is spaced and/or apart (e.g., spaced apart or separated) from a top surface of the semiconductor stack.

According to one or more embodiments of the present disclosure, an electronic device includes: a display module to an image; and a processor to transmit an image data signal to the display module, wherein the display module includes: a substrate; an organic film on the substrate; and a light emitting element on the organic film, wherein the organic film includes a monomer represented by Chemical Formula 1; a reactive unsaturated compound; a photoinitiator; and a solvent, wherein the organic film includes: 25 parts to 50 parts by weight of the monomer represented by the Chemical Formula 1; 5 parts to 10 parts by weight of the reactive unsaturated compound; 0.25 parts to 5 parts by weight of the photoinitiator; and 40 parts to 70 parts by weight of the solvent, with respect to (e.g., based on) 100 parts by weight of the organic film:

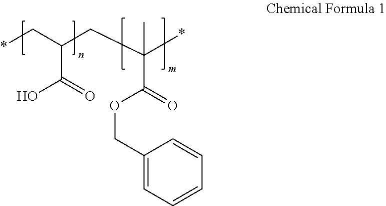

where n and m are integers.

The reactive unsaturated compound may include a compound represented by Chemical Formula 2:

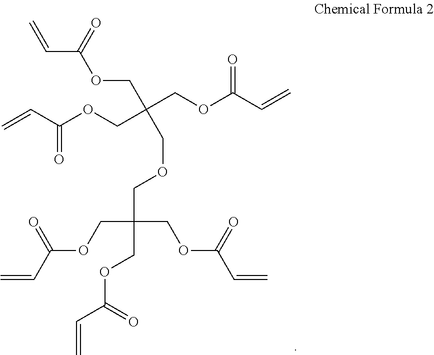 [SMILES: C=CC(=O)OCC(COCC(COC(=O)C=C)(COC(=O)C=C)COC(=O)C=C)(COC(=O)C=C)COC(=O)C=C]

In the organic film, R_{C═C/C═O} of Equation 1 may be 0.28 or more:

$${R}_{C = C / C = O} = {I}_{C = C} / {I}_{C = O} \qquad Equation 1$$

where the I_{C═C} is a C═C bond peak intensity in an infrared spectral spectrum, and the I_{C═O} is a C═O bond peak intensity in the infrared spectral spectrum.

An adhesion force of the organic film may be equal to or greater than 2.2 mN.

A modulus of the organic film may be equal to or less than 1.5 GPa.

According to an organic film composition for adhesion and a display device including the organic film composition for adhesion according to one or more embodiments, the content (e.g., amount) of a monomer may be increased and the content (e.g., amount) of a photoinitiator may be decreased, so that (e.g., such that) the fluidity and adhesiveness of the organic film composition for adhesion may be improved or enhanced.

According to the organic film composition for adhesion and the display device including the organic film composition for adhesion according to one or more embodiments, by applying the organic film composition for adhesion having improved or enhanced fluidity and adhesiveness to an organic film to fix a plurality of light emitting elements, an increase or enhancement in the curing rate of the organic film may be prevented or reduced before the plurality of light emitting elements are fixed to the display panel. Therefore, the fixability of the light emitting element transferred to the display panel may be improved or enhanced.

It should be noted that aspects and features of embodiments of the present disclosure are not limited to those described herein, and other aspects and features of certain embodiments of the present disclosure will be more apparent to those skilled in the art from the following descriptions.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is a perspective view illustrating a display device according to one or more embodiments;

FIG. 2 is a layout view illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a layout view illustrating pixels of a display area according to one or more embodiments;

FIG. 6 is a cross-sectional view illustrating an example of a cross section of the display panel corresponding to the line 11-11′ of FIG. 5;

FIG. 7 is a cross-sectional view illustrating an example of the area A of FIG. 6;

FIG. 8 is a layout view illustrating pixels of a display area according to one or more embodiments;

FIG. 9 is a cross-sectional view illustrating an example of a cross section of the display panel corresponding to the line 12-12′ of FIG. 8;

FIG. 10 is a plan view illustrating an example of the area B of FIG. 9;

FIG. 11 is a layout view illustrating pixels of a display area according to one or more embodiments;

FIG. 12 is a cross-sectional view illustrating an example of a cross section of the display panel corresponding to the line 13-13′ of FIG. 11;

FIG. 13 is a cross-sectional view illustrating an example of the area C of FIG. 12;

FIG. 14 is a graph illustrating the curing rate of an organic film composition for adhesion according to one or more embodiments of the present disclosure;

FIG. 15 is a graph obtained by measuring the adhesion force of an organic film composition for adhesion according to one or more embodiments of the present disclosure;

FIG. 16 is a graph obtained by measuring the modulus of an organic film composition for adhesion according to one or more embodiments of the present disclosure;

FIG. 17 is a graph obtained by measuring the bonding rate according to the temperature of the organic film composition for adhesion according to one or more embodiments of the present disclosure;

FIG. 18 illustrates a smart watch including a display device according to one or more embodiments;

FIG. 19 illustrates a virtual reality device including a display device according to one or more embodiments;

FIGS. 20 and 21 illustrate a virtual reality device including a display device according to one or more embodiments;

FIG. 22 illustrates a dashboard of an automobile and a center fascia including display devices according to one or more embodiments; and

FIG. 23 illustrates a transparent (e.g., substantially transparent) display device including a display device according to one or more embodiments.

### DETAILED DESCRIPTION

The aspects and features of embodiments of the present disclosure and the methods for achieving them will become clearer with reference to one or more embodiments described herein in more detail with the accompanying drawings. However, the present disclosure is not limited to the embodiments disclosed herein, but may be implemented in one or more different forms, and these embodiments are provided only to make the embodiments of the present disclosure complete and to fully inform those skilled in the art of the scope of the present disclosure, and the present disclosure is defined only by the scope of the appended claims and equivalents thereof.

The utilization of “may” if (e.g., when) describing embodiments of the present disclosure refers to “one or more embodiments of the present disclosure.”

In the context of the present disclosure and unless otherwise defined, the terms “use,” “using,” and “used” may be considered synonymous with the terms, “utilize,” “utilizing,” and “utilized,” respectively.

As used herein, the term “and/or” includes any and all combinations of one or more of the associated listed items. For example, “A and/or B” indicates cases where it is A, B, or both (e.g., simultaneously) A and B.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

The singular forms “a,” “an,” and “the” include plural references unless the context clearly requires otherwise.

As used herein, the terms “substantially,” “about,” and/or the like are used as terms of approximation and not as terms of degree and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will also be understood that if (e.g., when) a layer is referred to as being “on” or “above” another layer or substrate, it may be directly on or directly above the other layer or substrate, or intervening layers may also be present therebetween. In contrast, if (e.g., when) a layer is referred to as being “directly on” or “directly above” another layer or substrate, there are no intervening layers present therebetween.

The same reference numerals refer to substantially the same components throughout the specification.

The shapes, sizes, ratios, angles, numbers, and/or the like illustrated in the drawings to describe the embodiments are exemplary, and therefore embodiments of the present disclosure are not limited to the matters illustrated.

Although the terms “first”, “second”, and/or the like may be used herein to describe one or more suitable elements, these elements should not be limited by these terms. These terms may be used to distinguish one element from another element.

Thus, a first element as described in one or more embodiments may be termed a second element without departing from the scope of the present disclosure. The description of an element as a “first” element may not require or imply the presence of a second element or other elements. The terms “first”, “second”, and/or the like may also be used herein to differentiate different categories or sets of elements. For conciseness, the terms “first”, “second”, and/or the like may represent “first-category (or first-set)”, “second-category (or second-set)”, and/or the like, respectively.

Each feature of one or more embodiments of the present disclosure may be partially or entirely combined or combined with each other, and may be technically capable of one or more suitable interconnections and operations. Each embodiment may be implemented independently of each other or may be implemented together in a related relationship. One or more embodiments of the present disclosure are described herein in more detail with reference to the accompanying drawings.

In the context of the present disclosure and unless otherwise defined, plan view is an orthographic projection of a three-dimensional object from the position of a horizontal plane that intersects the object. For example, it is a top-down view, illustrating the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

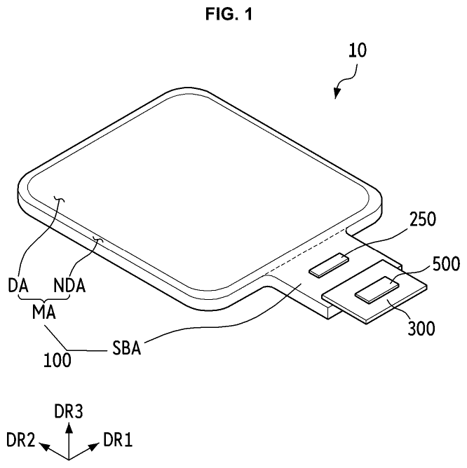

FIG. 1 is a perspective view illustrating a display device according to one or more embodiments.

Referring to FIG. 1, a display device 10, which is a device to display a moving image and/or a still image, may be used as a display screen of one or more suitable devices, such as a television, a laptop computer, a monitor, a billboard, and an Internet-of-Things (IOT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device, and an ultra-mobile PC (UMPC).

The display device 10 may be a light emitting display device, such as an organic light emitting display utilizing an organic light emitting diode, a quantum dot light emitting display including a quantum dot light emitting layer, an inorganic light emitting display including an inorganic semiconductor, and a micro light emitting display utilizing a micro or nano light emitting diode (LED). In the present disclosure, it is assumed that the display device 10 is a micro light emitting display device, but embodiments of the present disclosure are not limited thereto. For simplicity of description, an ultra-small light emitting diode is referred to hereafter as a light emitting element.

The display device 10 may include a display panel 100, a display driving circuit 250, a circuit board 300, and a power supply circuit 500.

The display panel 100 may, in plan view, be formed or provided in a rectangular shape (e.g., a substantially rectangular shape) having short sides in a first direction DR1 and long sides in a second direction DR2 crossing the first direction DR1. The corner where the short side in the first direction DR1 and the long side in the second direction DR2 meet may be rounded to have a selected (e.g., set or predetermined) curvature or may be right-angled. The planar shape of the display panel 100 is not limited to the rectangular shape and may be formed or provided in another polygonal shape (e.g., substantially polygonal shape), a circular shape (e.g., a substantially circular shape), or an elliptical shape (e.g., a substantially elliptical shape). The display panel 100 may be formed or provided to be flat (e.g., substantially flat), but embodiments of the present disclosure are not limited thereto. For example, the display panel 100 may include a curved portion formed or provided at left and right ends and having a constant curvature or a varying curvature. In one or more embodiments, the display panel 100 may be formed or provided flexibly so that (e.g., such that) it may be curved, bent, folded, or rolled.

The display panel 100 may include a main region MA and a sub-region SBA.

The main region MA may include a display area DA to display an image and a non-display area NDA that is a peripheral area of the display area DA. The display area DA may include a plurality of pixels to display an image. Each of the pixels may include a plurality of sub-pixels. For example, each of the pixels may include a first sub-pixel that emits first light, a second sub-pixel that emits second light, and a third sub-pixel that emits third light, but embodiments of the present disclosure are not limited thereto.

The sub-region SBA may protrude from one side of the main region MA in the second direction DR2. Although it is illustrated in FIG. 1 that the sub-region SBA is unfolded, the sub-region SBA may be bent and, in this case, arranged or provided on the bottom surface of the display panel 100. If (e.g., when) the sub-region SBA is bent, it may overlap the main region MA in a third direction DR3 that is a thickness direction of the display panel 100. The display driving circuit 250 may be arranged or provided in the sub-region SBA.

The display driving circuit 250 may generate signals and voltages to drive the display panel 100. The display driving circuit 250 may be formed or provided as an integrated circuit (IC) and attached onto the display panel 100 by a chip on glass (COG) method, a chip on plastic (COP) method, and/or an ultrasonic bonding method, but embodiments of the present disclosure are not limited thereto. For example, the display driving circuit 250 may be attached onto the circuit board 300 by a chip on film (COF) method.

The circuit board 300 may be attached to one end of the sub-region SBA of the display panel 100. Thus, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board, a printed circuit board, or a flexible film such as a chip on film.

The power supply circuit 500 may generate a plurality of panel driving voltages according to a power voltage from the outside. The power supply circuit 500 may be formed or provided as an integrated circuit (IC) and attached to the circuit board 300 by a COF method.

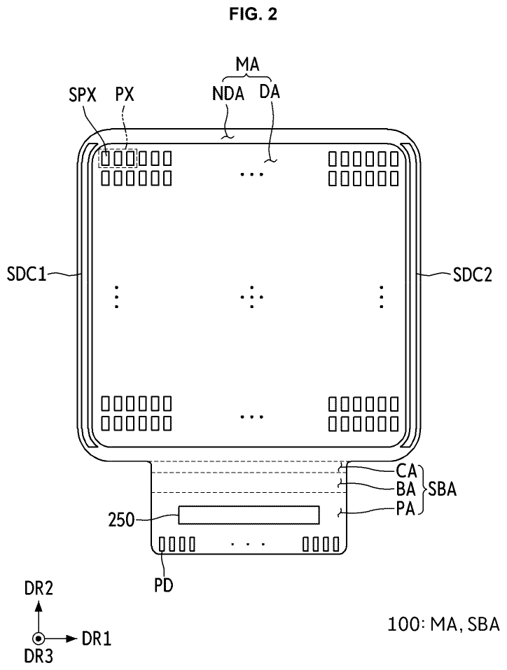

FIG. 2 is a layout view illustrating a display device according to one or more embodiments. It is exemplarily illustrated in FIG. 2 that the sub-region SBA is unfolded without being bent.

Referring to FIG. 2, the display panel 100 may include the main region MA and the sub-region SBA.

The main region MA may include the display area DA to display an image and the non-display area NDA that is a peripheral area of the display area DA. The display area DA may occupy most (e.g., substantially equal to or less than) of the main region MA. The display area DA may be located or provided at the center of the main region MA.

The display area DA may include a plurality of pixels PX to display an image, and each of the plurality of pixels PX may include a plurality of sub-pixels SPX. The pixel PX may be defined as a minimum unit sub-pixel group capable of expressing a white grayscale.

The non-display area NDA may be located or provided adjacent to the display area DA. The non-display area NDA may be an area outside the display area DA. The non-display area NDA may be located or provided to be around (e.g., surround) the display area DA. The non-display area NDA may be an edge area of the display panel 100.

A first scan driver SDC1 and a second scan driver SDC2 may be located or provided in the non-display area NDA. The first scan driver SDC1 may be located or provided at one side (for example, left side) of the display panel 100, and the second scan driver SDC2 may be located or provided at the other side (for example, right side) of the display panel 100, but embodiments of the present disclosure are not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive scan control signals inputted from the display driving circuit 250, generate scan signals in response to the scan control signals, and output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be located or provided under the display panel 100. In this case, the sub-region SBA may overlap the main region MA in the third direction DR3.

The sub-region SBA may include a connection area CA, a pad area PA, and a bending area BA.

The connection area CA may be an area protruding from one side of the main region MA in the second direction DR2. One side of the connection area CA may be in contact with the non-display area NDA of the main region MA, and the other side of the connection area CA may be in contact with the bending area BA.

The pad area PA may be an area on which pads PD and the display driving circuit 250 are located or provided. The display driving circuit 250 may be attached to driving pads of the pad area PA utilizing a conductive (e.g., electrically conductive) adhesive member, such as an anisotropic conductive film. The circuit board 300 may be attached to the pads PD of the pad area PA utilizing a conductive (e.g., electrically conductive) adhesive member, such as an anisotropic conductive film. One side of the pad area PA may be in contact with the bending area BA.

The bending area BA may be an area being bent. If (e.g., when) the bending area BA is bent, the pad area PA may be located or provided under the connection area CA and the main region MA. The bending area BA may be located or provided between the connection area CA and the pad area PA. One side of the bending area BA may be in contact with the connection area CA, and the other side of the bending area BA may be in contact with the pad area PA.

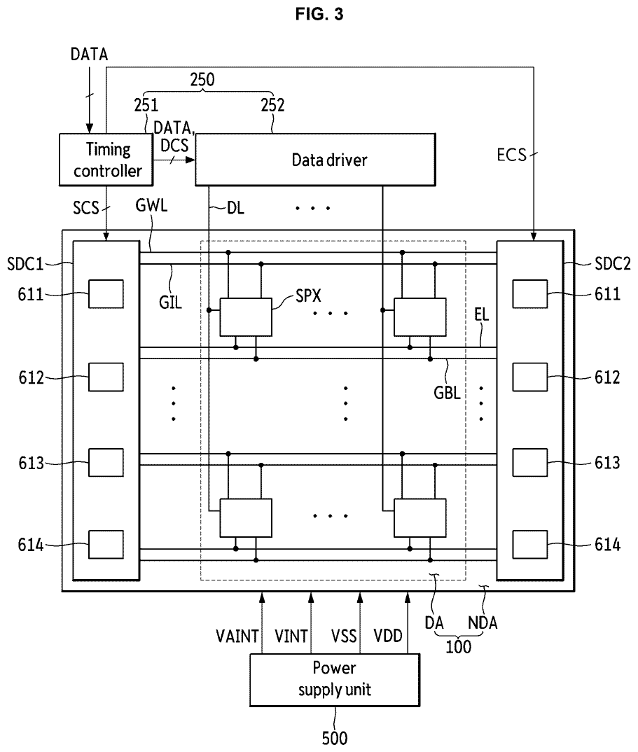

FIG. 3 is a block diagram illustrating a display device according to one or more embodiments.

Referring to FIG. 3, the display area DA may include the plurality of pixels PX, a plurality of scan lines SL, a plurality of emission control lines EL, and a plurality of data lines DL.

The plurality of pixels PX may be arranged or provided in a matrix form in the first direction DR1 and the second direction DR2. The plurality of scan lines SL and the plurality of emission control lines EL may extend in the first direction DR1, while being arranged or provided in the second direction DR2. The plurality of data lines DL may extend in the second direction DR2, while being arranged or provided in the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to any one write scan line GWL selected from among the plurality of write scan lines GWL, any one control scan line GCL selected from among the plurality of control scan lines GCL, any one initialization scan line GIL selected from among the plurality of initialization scan lines GIL, any one bias scan line GBL selected from among the plurality of bias scan lines GBL, any one emission control line EL selected from among the plurality of emission control lines EL, and any one data line DL selected from among the plurality of data lines DL. Each of the plurality of sub-pixels SPX may receive the data voltage of the data line DL according to the write scan signal of the write scan line GWL and may allow a light emitting element to emit light according to the data voltage.

The non-display area NDA may include the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission control signal output unit 614. Each of the write scan signal output unit 611, the initialization scan signal output unit 612, the bias scan signal output unit 613, and the emission control signal output unit 614 may receive a scan timing control signal SCS from a timing control circuit 251.

The write scan signal output unit 611 may generate write scan signals according to the scan timing control signal SCS of the timing control circuit 251 and output them sequentially to the write scan lines GWL.

The initialization scan signal output unit 612 may generate initialization scan signals in response to the scan timing control signal SCS and sequentially output them to the initialization scan lines GIL.

The bias scan signal output unit 613 may generate bias scan signals according to the scan timing control signal SCS and output them sequentially to the bias scan lines GBL. The emission control signal output unit 614 may generate emission control signals according to the scan timing control signal SCS and sequentially output them to the emission control lines EL.

The display driving circuit 250 may include a timing control circuit 251 and a data driving circuit 252.

The data driving circuit 252 may receive digital video data and a data timing control signal DCS from the timing control circuit 251. The data driving circuit 252 may convert the digital video data DATA into analog data voltages in response to the data timing control signal DCS and output them to the data lines DL. In this case, the sub-pixels SPX may be selected by the write scan signal of the first scan driver SDC1 and the second scan driver SDC2, and data voltages may be supplied to the selected sub-pixels SPX.

The timing control circuit 251 may receive digital video data DATA and timing signals from the outside. The timing control circuit 251 may generate the scan timing control signal SCS and the data timing control signal DCS to control the display panel 100 in response to the timing signals. The timing control circuit 400 may output the scan timing control signal SCS to the first scan driver SDC1 and the second scan driver SDC2. The timing control circuit 251 may output the digital video data DATA and the data timing control signal DCS to the data driving circuit 252.

The power supply circuit 500 may generate a plurality of panel driving voltages according to a power voltage supplied from the outside. For example, the power supply circuit 500 may generate a first power voltage VDD, a second power voltage VSS, a third power voltage VINT, and a fourth power voltage VAINT and supply them to the display panel 100.

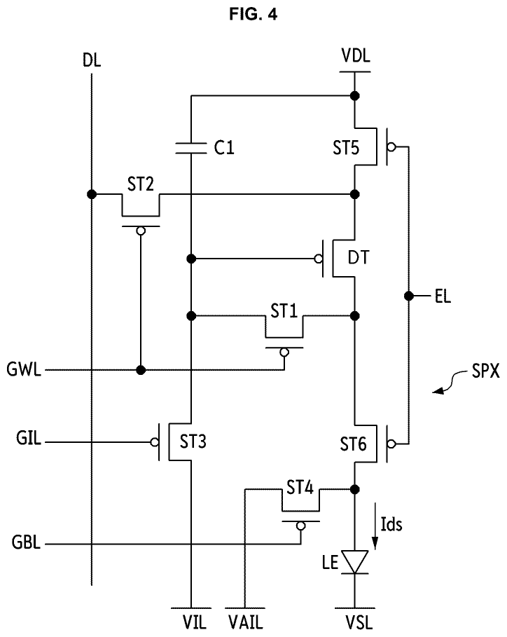

FIG. 4 is an equivalent circuit diagram illustrating a sub-pixel according to one or more embodiments.

Referring to FIG. 4, the sub-pixel SPX according to one or more embodiments may be connected to the scan lines GWL, GIL, and GBL, the emission control line EL, and the data line DL. For example, the sub-pixel SPX may be connected to the write scan line GWL, the initialization scan line GIL, the bias scan line GBL, the emission control line EL, and the data line DL.

The sub-pixel SPX according to one or more embodiments may include a driving transistor DT, switch elements, a capacitor C1, and a light emitting element LE. The switch elements may include the first to sixth transistors ST1, ST2, ST3, ST4, ST5, and ST6.

The driving transistor DT may include a gate electrode, a first electrode, and a second electrode. The driving transistor DT may control a drain-source current Ids (hereinafter, referred to as “driving current”) that flows between the first electrode and the second electrode according to a data voltage applied to the gate electrode.

The light emitting element LE may be a micro light emitting diode element.

The light emitting element LE may emit light according to a driving current Ids. The emission amount of the light emitting element LE may be proportional to the driving current Ids. The anode electrode of the light emitting element LE may be connected to the first electrode of the fourth transistor ST4 and the second electrode of the sixth transistor ST6, and the cathode electrode thereof may be connected to a second power line VSL to which a second power voltage is applied.

The capacitor C1 may be formed or provided between the gate electrode of the driving transistor DT and a first power line VDL to which a first power voltage is applied. The first power voltage may be the voltage having a level higher than that of the second power voltage. One electrode of the capacitor C1 may be connected to the gate electrode of the driving transistor DT, and the other electrode thereof may be connected to the first power line VDL.

As illustrated in FIG. 4, the first to sixth transistors ST1 to ST6 and the driving transistor DT may all be formed or provided as positive type or kind (p-type or kind) metal oxide semiconductor field effect transistors (MOSFETs). In this case, the active (e.g., electrically active) layer of each of the driving transistor DT and the first to sixth transistors ST1 to ST6 may include polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1 to ST6 are formed or provided as p-type or kind MOSFETs, they may be turned on if (e.g., when) a scan signal and an emission control signal of a gate low voltage are applied to the initialization scan line GIL, the write scan line GWL, the bias scan line GBL, and the emission line EL. One electrode of the third transistor ST3 may be connected to a first initialization voltage line VIL to which the third power voltage VINT (see FIG. 3) is applied, and one electrode of the fourth transistor ST4 may be connected to a second initialization voltage line VAIL to which the fourth power voltage VAINT (see FIG. 3) is applied. The third power voltage VINT (see FIG. 3) and the fourth power voltage VAINT (see FIG. 3) may be different voltages. Further, the third power voltage VINT (see FIG. 3) and the fourth power voltage VAINT (see FIG. 3) may be voltages having a level lower than that of the first power voltage VDD and having a level higher than that of the second power voltage VSS.

In one or more embodiments, the driving transistor DT, the second transistor ST2, the fourth transistor ST4, the fifth transistor ST5, and the sixth transistor ST6 may be configured or provided as p-type or kind metal oxide semiconductor field effect transistors (MOSFETs), and the first transistor ST1 and the third transistor ST3 may be configured or provided as negative type or kind (n-type or kind) MOSFETs. In this case, an active (e.g., electrically active) layer of each of the driving transistor DT, the second transistor ST2, the fourth transistor ST4, the fifth transistor ST5, and the sixth transistor ST6 configured or provided as the p-type or kind MOSFETs may include polysilicon, whereas an active (e.g., electrically active) layer of each of the first transistor ST1 and the third transistor ST3 configured or provided as the n-type or kind MOSFETs may include an oxide semiconductor. In one or more embodiments, because the first transistor ST1 and the third transistor ST3 are formed or provided as n-type or kind MOSFETs, the first transistor ST1 may be turned on if (e.g., when) the scan signal of a gate high voltage is applied, and the third transistor ST3 may be turned on if (e.g., when) the initialization scan signal of a gate high voltage is applied. In one or more embodiments, because the second transistor ST2, the fourth transistor ST4, the fifth transistor ST5, and the sixth transistor ST6 are configured or provided as the p-type or kind MOSFETs, they may be turned on if (e.g., when) an emission control signal and a scan signal of a gate low voltage are applied.

In one or more embodiments, if (e.g., when) the fourth transistor ST4 is formed or provided as an n-type or kind MOSFET, and the other transistors DT, ST1, ST2, ST3, ST5, and ST6 are formed or provided as p-type or kind MOSFETs, the active layer of the fourth transistor ST4 may include an oxide semiconductor, and the active layer of each of the other transistors DT, ST1, ST2, ST3, ST5, and ST6 may include polysilicon. Further, the fourth transistor ST4 may be turned on if (e.g., when) a scan signal of a gate high voltage is applied, whereas the other transistors DT, ST1, ST2, ST3, ST5, and ST6 may be turned on if (e.g., when) an emission control signal and a scan signal of a gate low voltage are applied.

In one or more embodiments, the first to sixth transistors ST1, ST2, ST3, ST4, ST5, and ST6 and the driving transistor DT may all be formed or provided as n-type or kind MOSFETs. In this case, the active layer of each of the driving transistor DT and the first to sixth transistors ST1, ST2, ST3, ST4, ST5, and ST6 may include an oxide semiconductor and may be turned on if (e.g., when) an emission control signal and a scan signal of a gate high voltage are applied.

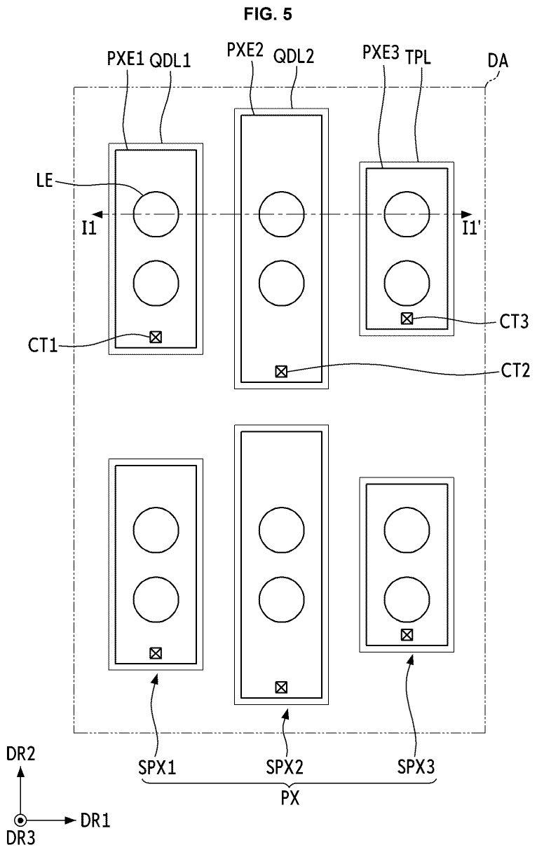

FIG. 5 is a layout view illustrating pixels of a display area according to one or more embodiments.

Referring to FIG. 5, each of the plurality of pixels PX of the display area DA may include three sub-pixels SPX1, SPX2, and SPX3, but embodiments of of the present disclosure are not limited thereto, and it may include four sub-pixels. If (e.g., when) each of the plurality of pixels PX includes three sub-pixels SPX1, SPX2, and SPX3, it may include a first sub-pixel SPX1, a second sub-pixel SPX2, and a third sub-pixel SPX3.

The plurality of pixels PX may be arranged or provided in a matrix. In each of the plurality of pixels PX, the first sub-pixel SPX1, the second sub-pixel SPX2, and the third sub-pixel SPX3 may be arranged or provided in the first direction DR1.

If (e.g., when) each of the plurality of pixels PX includes three sub-pixels SPX1, SPX2, and SPX3, the first sub-pixel SPX1 may emit first light, the second sub-pixel SPX2 may emit second light, and the third sub-pixel SPX3 may emit third light. Herein, the first light may be light of a blue wavelength band, the second light may be light of a green wavelength band, and the third light may be light of a red wavelength band. For example, the blue wavelength band may be a wavelength band of light whose main or predominant peak wavelength is in the range of about 370 nm to about 460 nm, the green wavelength band may be a wavelength band of light whose main or predominant peak wavelength is in the range of about 480 nm to about 560 nm, and the red wavelength band may be a wavelength band of light whose main or predominant peak wavelength is in the range of about 600 nm to about 750 nm.

In one or more embodiments, if (e.g., when) each of the plurality of pixels PX includes four sub-pixels, the first sub-pixel may emit first light, the second sub-pixel and the fourth sub-pixel may emit second light, and the third sub-pixel may emit third light. In one or more embodiments, the first sub-pixel may emit first light, the second sub-pixel may emit second light, the third sub-pixel may emit third light, and the fourth sub-pixel may emit fourth light. At this time, the fourth light may be white light.

The first sub-pixel SPX1 may include a first pixel electrode PXE1, a plurality of light emitting elements LE, and a first light conversion layer QDL1. The second sub-pixel SPX2 may include a second pixel electrode PXE2, a plurality of light emitting elements LE, and a second light conversion layer QDL2. The third sub-pixel SPX3 may include a third pixel electrode PXE3, a plurality of light emitting elements LE, and a light transmitting layer (or third light conversion layer) TPL.

Each of the first pixel electrode PXE1, the second pixel electrode PXE2, and the third pixel electrode PXE3 may, in plan view, be formed or provided in a rectangular shape (e.g., a substantially rectangular shape) having short sides in the first direction DR1 and long sides in the second direction DR2. The area of the first sub-pixel SPX1, the area of the second sub-pixel SPX2, and the area of the third sub-pixel SPX3 may be set or predetermined depending on the light conversion efficiency of the first light conversion layer QDL1 and the light conversion efficiency of the second light conversion layer QDL2. For example, the area of the sub-pixel may increase as the light conversion efficiency decreases.

For example, as illustrated in FIG. 5, if (e.g., when) the light conversion efficiency of the second light conversion layer QDL2 is less than the light conversion efficiency of the first light conversion layer QDL1, the area of the second pixel electrode PXE2 may be larger than the area of the first pixel electrode PXE1. Further, the light transmitting layer TPL may directly transmit the light of the light emitting element LE, whereas the first light conversion layer QDL1 needs or is desired to convert the light, so that (e.g., such that) the area of the first pixel electrode PXE1 may be larger than the area of the third pixel electrode PXE3.

Each of the pixel electrodes PXE1, PXE2, and PXE3 may be electrically connected to at least one transistor through a pixel connection hole CT1/CT2/CT3. For example, each of the pixel electrodes PXE1, PXE2, and PXE3 may be electrically connected to the second electrode of the fourth transistor ST4 (see FIG. 4) and the second electrode of the sixth transistor ST6 (see FIG. 4) of the corresponding sub-pixel.

The plurality of light emitting elements LE may be arranged or provided on each of the pixel electrodes PXE1, PXE2, and PXE3. Substantially the same number of light emitting elements LE may be arranged or provided on each of the pixel electrodes PXE1, PXE2, and PXE3. For example, two light emitting elements LE may be arranged or provided on each of the pixel electrodes PXE1, PXE2, and PXE3. The plurality of light emitting elements LE may emit third light, for example, light of a blue wavelength band, but embodiments of the present disclosure are not limited thereto. If (e.g., when) the light emitting element LE of the first sub-pixel SPX1 emits first light, the light emitting element LE of the second sub-pixel SPX2 emits second light, and the light emitting element LE of the third sub-pixel SPX3 emits third light, the light conversion layers QDL1 and QDL2 and the light transmitting layer TPL may not be provided.

The first light conversion layer QDL1 may completely (e.g., substantially completely) overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may emit light by converting or shifting the peak wavelength of incident light to another specific (e.g., set or predetermined) peak wavelength. For example, the first light conversion layer QDL1 may convert or shift the third light emitted from the plurality of light emitting elements LE of the first sub-pixel SPX1 into the first light.

The second light conversion layer QDL2 may completely (e.g., substantially completely) overlap the plurality of light emitting elements LE of the second sub-pixel SPX2 and the second pixel electrode PXE2. The area of the second light conversion layer QDL2 may be larger than the area of the second pixel electrode PXE2. The second light conversion layer QDL2 may emit light by converting or shifting the peak wavelength of incident light to another specific (e.g., set or predetermined) peak wavelength. For example, the second light conversion layer QDL2 may convert or shift the third light emitted from the plurality of light emitting elements LE of the second sub-pixel SPX2 into the second light.

The light transmitting layer TPL may completely (e.g., substantially completely) overlap the plurality of light emitting elements LE of the third sub-pixel SPX3 and the third pixel electrode PXE3. The light transmitting layer TPL may directly transmit incident light. For example, the light transmitting layer TPL may directly transmit the third light emitted from the plurality of light emitting elements LE of the third sub-pixel SPX3.

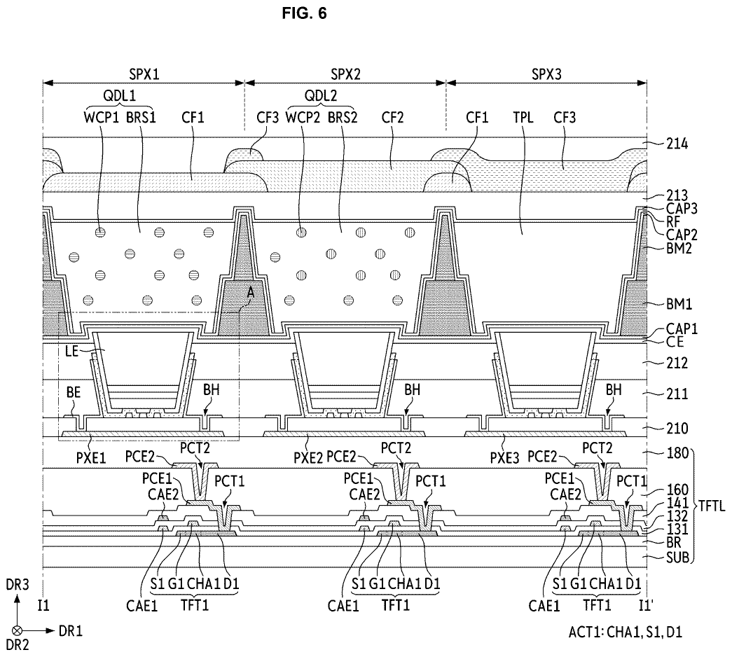

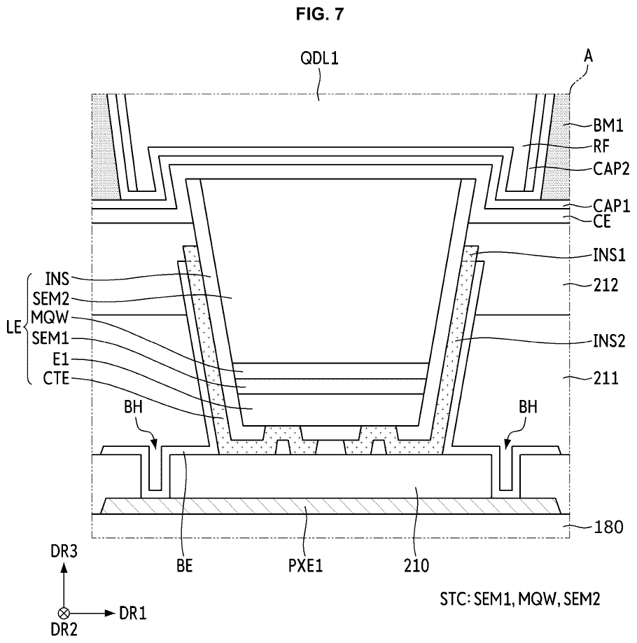

FIG. 6 is a cross-sectional view illustrating an example of a cross section of the display panel corresponding to the line 11-11′ of FIG. 5. FIG. 7 is a cross-sectional view illustrating an example of the area A of FIG. 6.

Referring to FIGS. 6 and 7, the substrate SUB may include an insulating (e.g., electrically insulating) material, such as glass and/or a polymer resin. If (e.g., when) the substrate SUB includes a polymer resin, it may be a flexible substrate that may be stretched. The polymer resin may include an acryl resin, an epoxy resin, a phenolic resin, a polyamide resin, and/or a polyimide resin.

A barrier film BR may be located or provided on the substrate SUB. The barrier film BR may be a film to protect transistors of the thin film transistor layer TFTL and the light emitting elements LE arranged or provided on the thin film transistor layer TFTL from moisture permeating through the substrate SUB which is susceptible to moisture permeation. The barrier film BR may be formed or provided as a plurality of inorganic films that are alternately stacked.

The thin film transistor TFT1 may be located or provided on the barrier film BR. The thin film transistor TFT1 may be any one selected from the fourth transistor ST4 and the sixth transistor ST6 as illustrated in FIG. 4. The thin film transistor TFT1 may include a first active layer ACT1 and a first gate electrode G1.

The first active layer ACT1 of the thin film transistor TFT1 may be located or provided on the barrier film BR. The first active layer ACT1 of the thin film transistor TFT1 may include polycrystalline silicon, monocrystalline silicon, low-temperature polycrystalline silicon, and/or amorphous (e.g., non-crystalline) silicon. In one or more embodiments, the first active layer ACT1 of the thin film transistor TFT1 may include an oxide semiconductor containing IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel region CHA1, a first source region S1, and a first drain region D1. The first channel region CHA1 may be a region overlapping a first gate electrode G1 in the third direction DR3 that is a thickness direction of the substrate SUB. The first source region S1 may be located or provided on one side of the first channel region CHA1, and the first drain region D1 may be located or provided on the other side of the first channel region CHA1. The first source region S1 and the first drain region D1 may be regions that do not overlap the first gate electrode G1 in the third direction DR3. The first source region S1 and the first drain region D1 may be regions having conductivity (e.g., electrical conductivity) by doping a semiconductor material with ions.

A first gate insulating layer 131 may be located or provided on a first channel region CHA1, a first source region S1, and a first drain region D1 of the thin film transistor TFT1.

A first gate metal layer may be located or provided on the first gate insulating layer 131. The first gate metal layer may include the first gate electrode G1 and the first capacitor electrode CAE1 of the thin film transistor TFT1. The first gate electrode G1 may overlap the first active layer ACT1 in the third direction DR3. Although it is illustrated in FIG. 6 that the first gate electrode G1 and the first capacitor electrode CAE1 are spaced and/or apart (e.g., spaced apart or separated) from each other, the first gate electrode G1 and the first capacitor electrode CAE1 may be electrically and/or physically connected to each other if (e.g., when) the thin film transistor TFT1 is the driving transistor DT of FIG. 4. In one or more embodiments, if (e.g., when) the thin film transistor TFT1 is any one selected from among the first to sixth transistors ST1 to ST6 of FIG. 4, the first gate electrode G1 and the first capacitor electrode CAE1 may not be electrically and/or physically connected to each other.

A second gate insulating layer 132 may be located or provided on the first gate electrode G1 and the first capacitor electrode CAE1 of the thin film transistor TFT1.

A second gate metal layer may be located or provided on the second gate insulating layer 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating layer 132 has a selected (e.g., set or predetermined) dielectric constant, the capacitor C1 (FIG. 4) may be formed or provided by the first capacitor electrode CAE1, the second capacitor electrode CAE2, and the second gate insulating layer 132 between the first capacitor electrode CAE1 and the second capacitor electrode CAE2.

A first interlayer insulating layer 141 may be located or provided on the second capacitor electrode CAE2.

A first data metal layer may be located or provided on the interlayer insulating film 141. The first data metal layer may include a first source connection electrode PCE1. The first source connection electrode PCE1 may be connected to the first drain region D1 of the first active layer ACT1 through a first source contact hole PCT1 penetrating the first gate insulating film 131, the second gate insulating film 132, and the interlayer insulating film 141.

A first planarization film 160 to flatten a stepped portion formed or provided by the thin film transistor TFT1 may be located or provided on the first source connection electrode PCE1.

A second data metal layer may be located or provided on the first planarization film 160. The second data metal layer may include a second source connection electrode PCE2. The second source connection electrode PCE2 may be connected to the first source connection electrode PCE1 through a second source contact hole PCT2 penetrating the first planarization film 160.

A second planarization film 180 may be located or provided on the second source connection electrode PCE2.

The barrier film BR, the first gate insulating film 131, the second gate insulating film 132, and the interlayer insulating film 141 may be formed or provided as an inorganic film, such as silicon nitride (e.g., SiNₓ, wherein 0<x≤5; e.g., Si₃N₄), silicon nitride oxide or silicon oxynitride (e.g., SiOₓN_{y}, wherein 0<x≤5 and 0≤y≤5; e.g., SiON or Si₂N₂O), silicon oxide (e.g., SiOx, wherein 0<x≤5; e.g., SiO₂), titanium oxide (e.g., TiOₓ, wherein 0<x≤5; e.g., TiO₂), and/or aluminum oxide (e.g., AlOₓ, wherein 0<x≤5; e.g., Al₂O₃).

The first gate metal layer, the second gate metal layer, the first data metal layer, and the second data metal layer may be formed or provided as a single layer or two or more layers including any one selected from among molybdenum (Mo), aluminum (Al), chromium (Cr), gold (Au), titanium (Ti), nickel (Ni), neodymium (Nd), and copper (Cu) or an alloy thereof.

The first planarization film 160 and the second planarization film 180 may be formed or provided as organic films, such as an acryl resin, an epoxy resin, a phenolic resin, a polyamide resin, a polyimide resin, and/or the like.

A light emitting element layer may be located or provided on the second planarization film 180. The light emitting element layer may include the pixel electrodes PXE1, PXE2, and PXE3, the light emitting elements LE, a common electrode CE, and organic films 210, 211, and 212.

A pixel electrode layer may be located or provided on the second planarization film 180. The pixel electrode layer may include the first pixel electrode PXE1, the second pixel electrode PXE2, and the third pixel electrode PXE3. Each of the pixel electrodes PXE1, PXE2, and PXE3 may be connected to the second source connection electrode PCE2 through the pixel connection hole CT1/CT2/CT3 (see FIG. 5) penetrating the second planarization film 180. Each of the pixel electrodes PXE1, PXE2, and PXE3 may be connected to the first source region S1 or the first drain region D1 of the thin film transistor TFT1 through the first source connection electrode PCE1 and the second source connection electrode PCE2. Accordingly, the voltage controlled or selected by the thin film transistor TFT1 may be applied to each of the pixel electrodes PXE1, PXE2, and PXE3.

The pixel electrode layer may be formed or provided as a single layer or two or more layers including any one selected from among molybdenum (Mo), aluminum (Al), chromium (Cr), gold (Au), titanium (Ti), nickel (Ni), neodymium (Nd), and copper (Cu) or an alloy thereof. For example, in order to lower the resistance of each of the pixel electrodes PXE1, PXE2, and PXE3, the pixel electrode layer may be made of copper (Cu) having a low surface resistance.

A first organic film 210 may be located or provided on each of the pixel electrodes PXE1, PXE2, and PXE3. The first organic film 210 may serve to temporarily fix or adhere the plurality of light emitting elements LE in order to prevent them from tilting and/or falling (or to reduce a degree to or occurrence of which the plurality of light emitting elements LE tilts and/or falls) during the process of transferring the plurality of light emitting elements LE to the display panel 100. For example, the first organic film 210 may be a film for false adhesion of the plurality of light emitting elements LE on each of the pixel electrodes PXE1, PXE2, and PXE3. To facilitate false adhesion, the thickness of the first organic film 210 may be greater than the thickness of each of the pixel electrodes PXE1, PXE2, and PXE3 and may be greater than the thickness of a contact electrode CTE.

The first organic film 210 may be a main or predominant feature of the present disclosure, and thus will be described in more detail herein.

The first organic film 210 may be a photosensitive organic film, such as a photoresist. In one or more embodiments, the first organic film 210 may include an acryl resin, an epoxy resin, a phenolic resin, a polyamide resin, a polyimide resin, and/or the like.

The plurality of light emitting elements LE may be located or provided on the first organic film 210. In FIG. 6, each of the plurality of light emitting elements LE refers to an LED having a structure in which a semiconductor layer SEM1, an active layer MQW, and a second semiconductor layer SEM2 extending in the third direction DR3 are sequentially arranged or provided in the third direction DR3 that is a vertical direction.

Each of the plurality of light emitting elements LE may have a reverse tapered cross-sectional shape. For example, each of the plurality of light emitting elements LE may have a trapezoidal (e.g., substantially trapezoidal) cross-sectional shape in which the width of the top surface is wider than the width of the bottom surface.

Each of the plurality of light emitting elements LE may include an inorganic material, such as gallium nitride (GaN). Each of the plurality of light emitting elements LE may have a length of several μm to several hundreds of μm in each of the first direction DR1, the second direction DR2, and the third direction DR3. For example, each of the plurality of light emitting elements LE may have a length of about 100 μm or less in each of the first direction DR1, the second direction DR2, and the third direction DR3.

Each of the plurality of light emitting elements LE may be formed or provided by growing on a semiconductor substrate, such as a silicon substrate and/or a sapphire substrate. The plurality of light emitting elements LE may be directly transferred from the semiconductor substrate onto the pixel electrodes PXE1, PXE2, and PXE3 of the display panel 100. In one or more embodiments, the plurality of light emitting elements LE may be transferred onto the pixel electrodes PXE1, PXE2, and PXE3 of the display panel 100 through an electrostatic method utilizing an electrostatic head and/or a stamping method utilizing an elastic polymer material, such as polydimethylsiloxane (PDMS) and/or silicon as a transfer substrate.

The light emitting element LE may include a conductive layer E1, a semiconductor stack STC, the contact electrode CTE, and a protective film INS. The semiconductor stack STC may include the first semiconductor layer SEM1, the active layer MQW, and the second semiconductor layer SEM2 that are sequentially arranged or provided in the third direction DR3.

The conductive layer E1 may be located or provided on the bottom surface of the first semiconductor layer SEM1. Although it is illustrated in FIG. 7 that the conductive layer E1 covers the entire (e.g., substantially entire) bottom surface of the first semiconductor layer SEM1, embodiments of the present disclosure are not limited thereto. For example, the conductive layer E1 may be located or provided on a part of the bottom surface of the first semiconductor layer SEM1. The conductive layer E1 may include any one selected from among molybdenum (Mo), aluminum (Al), chromium (Cr), gold (Au), titanium (Ti), nickel (Ni), neodymium (Nd), and copper (Cu).

The first semiconductor layer SEM1 may be located or provided on the contact electrode CTE. The length in the first direction DR1 or the length in the second direction DR2 of the bottom surface of the first semiconductor layer SEM1 may be smaller than the length in the first direction DR1 or the length in the second direction DR2 of the contact electrode CTE. The first semiconductor layer SEM1 may be a semiconductor material layer, for example, gallium nitride (GaN), doped with a first conductivity (e.g., electrical conductivity) type or kind dopant, such as magnesium (Mg), zinc (Zn), calcium (Ca), strontium (Sr), barium (Ba), and/or the like.

The active layer MQW may be located or provided on the first semiconductor layer SEM1. The active material layer MQWL may include substantially the same semiconductor material layer as the first semiconductor material layer SEML1 and the second semiconductor material layer SEML2. For example, if (e.g., when) the first semiconductor material layer SEML1 and the second semiconductor material layer SEML2 include gallium nitride (GaN), the active material layer MQWL may also include gallium nitride (GaN). For example, the active material layer MQWL may include at least one of gallium nitride (GaN), indium gallium nitride (InGaN), or aluminum gallium nitride (AlGaN). The active layer MQW may emit light by coupling of electron-hole pairs according to an electrical signal applied through the first semiconductor layer SEM1 and the second semiconductor layer SEM2.

The active layer MQW may include a material having a single quantum well structure or a two or more quantum well structure. If (e.g., when) the active layer MQW contains a material having a two or more quantum well structure, the active layer MQW may have the structure in which a plurality of well layers and barrier layers are alternately stacked. At this time, the well layer may include InGaN, and the barrier layer may include GaN and/or AlGaN, but embodiments of the present disclosure are not limited thereto. In one or more embodiments, the active layer MQW may have a structure in which semiconductor materials having large band gap energy and semiconductor materials having small band gap energy are alternately stacked, and may include other group III to V semiconductor materials according to the wavelength band of the emitted light.

If (e.g., when) the active layer MQW includes indium gallium nitride (InGaN), the color of emitted light may vary depending on the content (e.g., amount) of indium (In). For example, as the content (e.g., amount) of indium (In) increases, the wavelength band of the light emitted by the active layer may shift to the red wavelength band, and as the content (e.g., amount) of indium (In) decreases, the wavelength band of the light emitted by the active layer may shift to the blue wavelength band. For example, the active layer MQW of the light emitting element LE that emits the third light (light in the blue wavelength band) may contain about 10 wt % to 20 wt % of indium (In).

The second semiconductor layer SEM2 may be located or provided on the active layer MQW. The second semiconductor layer SEM2 may be a semiconductor material layer, for example, gallium nitride (GaN), doped with a second conductivity (e.g., electrical conductivity) type or kind dopant, such as silicon (Si), germanium (Ge), and/or tin (Sn).

The electron blocking layer may be located or provided between the first semiconductor layer SEM1 and the active layer MQW. The electron blocking layer may be a layer to suppress or prevent too many electrons or the substantial number of electrons from flowing into the active layer MQW (or to reduce a degree to or occurrence of which too many electrons or the substantial number of electrons flow into the active layer MQW). For example, the electron blocking layer may be AlGaN and/or p-AlGaN doped with p-type or kind Mg. The electron blocking layer may not be provided.

The superlattice layer may be located or provided between the active layer MQW and the second semiconductor layer SEM2. The superlattice layer may be a layer to relieve or reduce stress between the second semiconductor layer SEM2 and the active layer MQW. For example, the superlattice layer may include InGaN and/or GaN. The superlattice layer may not be provided.

The protective film INS may be located or provided on the side surface of the first semiconductor layer SEM1, the side surface of the active layer MQW, and the side surface of the second semiconductor layer SEM2. The protective film INS may be a layer to protect the side surface of the light emitting element LE. The protective film INS may be formed or provided as an inorganic film, such as silicon nitride (e.g., SiNₓ, wherein 0<x≤2; e.g., Si₃N₄), silicon nitride oxide or silicon oxynitride (e.g., SiOₓN_{y}, wherein 0<x≤2 and 0≤y≤2; e.g., SiON or Si₂N₂O), silicon oxide (e.g., SiOx, wherein 0<x≤2; e.g., SiO₂), titanium oxide (e.g., TiOₓ, wherein 0<x≤2; e.g., TiO₂), and/or aluminum oxide (e.g., AlOₓ, wherein 0<x≤2; e.g., Al₂O₃).

The contact electrode CTE may be disposed or provided on the protective film INS. The contact electrode CTE may be located or provided between the first organic film 210 and the protective film INS. The contact electrode CTE may be in contact with the first organic film 210.

Although it is illustrated in FIGS. 6 and 7 that the contact electrode CTE of each of the light emitting elements LE is located or provided on the first organic film 210, embodiments of the present disclosure are not limited thereto. For example, the first organic film 210 may be located or provided on a part of the side surface and the bottom surface of the contact electrode CTE of each of the light emitting elements LE. In one or more embodiments, the first organic film 210 may be located or provided on the side surface of the conductive layer E1 of each of the light emitting elements LE. In one or more embodiments, the first organic film 210 may be located or provided on the side surface of the first semiconductor layer SEM1, the side surface of the active layer MQW, and the side surface of the second semiconductor layer SEM2 of each of the light emitting elements LE. In this case, the first organic film 210 may be located or provided on a part of the side surface of the second semiconductor layer SEM2.

The contact electrode CTE may be connected to the conductive layer E1 that is exposed without being covered by the protective film INS. Therefore, even if (e.g., when) any one of the contact electrodes CTE is not connected to the conductive layer E1 due to a process error, another contact electrode CTE may be connected to the conductive layer E1, thereby preventing the occurrence of a defect (or reducing a degree or occurrence of a defect) in which the light emitting element LE is not turned on.

If (e.g., when) the contact electrode CTE is made of a metal having high reflectivity, the light traveling in the lateral direction of the light emitting element LE among the light emitted from the active layer MQW of the light emitting element LE may be reflected by the plurality of contact electrodes CTE and emitted to the top surface of the light emitting element LE. Accordingly, because light loss from the light emitting element LE may be reduced, the light efficiency of the light emitting element LE may be increased or enhanced. Therefore, in order to increase or enhance the light efficiency of the light emitting element LE, it is desirable that the contact electrode CTE is located or provided to cover most (e.g., substantially equal to or less than) of the side surface of the semiconductor stack STC.

The contact electrode CTE may include any one selected from among molybdenum (Mo), aluminum (Al), chromium (Cr), gold (Au), titanium (Ti), nickel (Ni), neodymium (Nd), and copper (Cu). For example, the plurality of contact electrodes CTE may be formed or provided in a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) in order to increase or enhance the reflectivity.

The connection electrode BE may connect the contact electrode CTE of the light emitting element LE to any one selected from among the pixel electrodes PXE1, PXE2, and PXE3. The connection electrode BE may be connected to any one selected from among the pixel electrodes PXE1, PXE2, and PXE3 exposed through a connection hole BH penetrating the first organic film 210. Further, the connection electrode BE may be located or provided on the top surface of the first organic layer 210 and the side surface of the contact electrode CTE. Further, the connection electrode BE may be located or provided on a part of the side surface of the light emitting element LE. For example, the connection electrode BE may be located or provided on a part of the protective film INS of the light emitting element LE.

The connection electrode BE may include any one selected from among molybdenum (Mo), aluminum (Al), chromium (Cr), gold (Au), titanium (Ti), nickel (Ni), neodymium (Nd), and copper (Cu). In one or more embodiments, the connection electrode BE may include a transparent (e.g., substantially transparent) conductive (e.g., electrically conductive) material (TCO), such as indium tin oxide (ITO) and/or indium zinc oxide (IZO) capable of transmitting light.

If (e.g., when) the connection electrode BE includes a metal material having high reflectivity, such as aluminum (Al), the light traveling in the lateral direction of the light emitting element LE among the light emitted from the active layer MQW of the light emitting element LE may be reflected from the connection electrode BE and travel in the upward direction of the light emitting element LE. Accordingly, because light loss from the light emitting element LE may be reduced, the light efficiency of the light emitting element LE may be increased or enhanced.

A third organic film 211 may be located or provided to cover a part of the side surface of each of the plurality of light emitting element LE. Further, the third organic film 211 may be located or provided to cover the connection electrode BE, but at least a part of the connection electrode BE may be exposed without being covered by the third organic film 211.

A fourth organic film 212 may be located or provided on the third organic film 211. The fourth organic film 212 may be located or provided to cover a part of the side surface of each of the plurality of light emitting elements LE. The fourth organic film 212 may be located or provided on at least a part of the connection electrode BE that is exposed without being covered by the third organic film 211. The top surface of each of the plurality of light emitting elements LE may be exposed without being covered by the fourth organic film 212.

The third organic film 211 and the fourth organic film 212 may be the layers to flatten the stepped portion caused by the plurality of light emitting elements LE. If (e.g., when) the third organic film 211 has a height to cover most (e.g., substantially equal to or less than) of the side surfaces of the plurality of light emitting elements LE, the fourth organic film 212 may not be provided.

The common electrode CE may be located or provided on the top surface of each of the plurality of light emitting elements LE and the top surface of the fourth organic film 212. The common electrode CE may be a common layer that is commonly formed or provided for the first sub-pixel SPX1, the second sub-pixel SPX2, and the third sub-pixel SPX3. The common electrode CE may include a transparent (e.g., substantially transparent) conductive (e.g., electrically conductive) material (TCO), such as indium tin oxide (ITO) and/or indium zinc oxide (IZO) capable of transmitting light.

In one or more embodiments, the pixel electrodes PXE1, PXE2, and PXE3 may be referred to as an anode electrode or a first electrode, and the common electrode CE may be referred to as a cathode electrode or a second electrode.

A first capping layer CAP1 may be located or provided on the common electrode CE.

A light blocking layer BM, the first light conversion layer QDL1, the second light conversion layer QDL2, and the light transmitting layer TPL may be arranged or provided on the first capping layer CAP1. The first light conversion layer QDL1, the second light conversion layer QDL2, and the light transmitting layer TPL may be formed or provided by partitioning the light blocking layer BM. Therefore, the first light conversion layer QDL1 may be located or provided on the first capping layer CAP1 in the first sub-pixel SPX1, the second light conversion layer QDL2 may be located or provided on the first capping layer CAP1 in the second sub-pixel SPX2, and the light transmitting layer TPL may be located or provided on the first capping layer CAP1 in the third sub-pixel SPX3. The light blocking layer BM may overlap the third organic film 211 and the fourth organic film 212 in the third direction DR3 and may not overlap the plurality of light emitting elements LE.

The first light conversion layer QDL1 may convert a part of the third light (e.g., light in the blue wavelength band) incident from the light emitting element LE into the first light (e.g., light in the red wavelength band). The first light conversion layer QDL1 may include a first base resin BRS1 and a first wavelength conversion particle WCP1. The first base resin BRS1 may include a light-transmissive organic material. The first wavelength conversion particle WCP1 may convert a part of the third light (e.g., light in the blue wavelength band) incident from the light emitting element LE into the first light (e.g., light in the red wavelength band).

The second light conversion layer QDL2 may convert a part of the third light (e.g., light in the blue wavelength band) incident from the light emitting element LE into the second light (e.g., light in the green wavelength band). The second light conversion layer QDL2 may include a second base resin BRS2 and second wavelength conversion particles WCP2. The second base resin BRS2 may contain a light-transmissive organic material. The second wavelength conversion particle WCP2 may convert a part of the third light (e.g., light in the blue wavelength band) incident from the light emitting element LE into the second light (e.g., light in the green wavelength band).

The light transmitting layer TPL may include a light-transmissive organic material.

For example, the first base resin BRS1, the second base resin BRS2, and the light transmitting layer TPL may include an epoxy-based resin, an acrylic-based resin, a cardo-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially stacked. The length of the first light blocking layer BM1 in the first direction DR1 or the length of the first light blocking layer BM1 in the second direction DR2 may be longer than the length of the second light blocking layer BM2 in the first direction DR1 or the length of the second light blocking layer BM2 in the second direction DR2. The first light blocking layer BM1 and the second light blocking layer BM2 may be formed or provided as organic films, such as an acryl resin, an epoxy resin, a phenolic resin, a polyamide resin, a polyimide resin, and/or the like. The first light blocking layer BM1 and the second light blocking layer BM2 may include a light blocking material to prevent light of the light emitting element LE of any one sub-pixel from traveling to the neighboring sub-pixel (or to reduce a degree to or occurrence of which light of the light emitting element LE of any one sub-pixel travels to the neighboring sub-pixel). For example, the first light blocking layer BM1 and the second light blocking layer BM2 may contain an organic block pigment and/or an inorganic black pigment, such as carbon black and/or the like.

The second capping layer CAP2 may be located or provided on the first capping layer CAP1 and the light blocking layer BM. The second capping layer CAP2 may be located or provided on the side and top surfaces of the light blocking layer BM. For example, the second capping layer CAP2 may be located or provided on the side surface of the first light blocking layer BM1 and the side and top surfaces of the second light blocking layer BM2.

A reflection film RF may be located or provided between the light blocking layer BM and the first light conversion layer QDL1, between the light blocking layer BM and the second light conversion layer QDL2, and between the light blocking layer BM and the light transmitting layer TPL. The reflection film RF may be located or provided on the second capping layer CAP2 located or provided on the side surface of the first light blocking layer BM1 and the side surface of the second light blocking layer BM2. The reflection film RF may serve to reflect light traveling in the lateral direction from the first light conversion layer QDL1, the second light conversion layer QDL2, and the light transmitting layer TPL.

The reflection film RF may include a metal material having high reflectivity, such as aluminum (Al). The thickness of the reflection film RF may be about 0.1 μm.

In one or more embodiments, the reflection film RF may include M (M being an integer of 2 or more) pairs of first layers and M (M being an integer of 2 or more) pairs of second layers having different refractive indices to serve as a distributed bragg reflector (DBR). In this case, M pairs of first layers and M pairs of second layers may be located or provided alternately. The first layer and the second layer may be formed or provided as inorganic films, such as silicon nitride (e.g., SiNₓ, wherein 0<x≤5; e.g., Si₃N₄), silicon nitride oxide or silicon oxynitride (e.g., SiOₓN_{y}, wherein 0<x≤5 and 0≤y≤5; e.g., SiON or Si₂N₂O), silicon oxide (e.g., SiOx, wherein 0<x≤5; e.g., SiO₂), titanium oxide (e.g., TiOₓ, wherein 0<x≤5; e.g., TiO₂), and/or aluminum oxide (e.g., AlOₓ, wherein 0<x≤5; e.g., Al₂O₃).

The third capping layer CAP3 may be located or provided on the second capping layer CAP2, the first light conversion layer QDL1, the second light conversion layer QDL2, and the light transmitting layer TPL.

The first capping layer CAP1, the second capping layer CAP2, and the third capping layer CAP3 may be formed or provided as inorganic films, such as silicon nitride (e.g., SiNₓ, wherein 0<x≤2; e.g., Si₃N₄), silicon nitride oxide or silicon oxynitride (e.g., SiOₓN_{y}, wherein 0<x≤2 and 0≤y≤2; e.g., SiON or Si₂N₂O), silicon oxide (e.g., SiOx, wherein 0<x≤2; e.g., SiO₂), titanium oxide (e.g., TiOₓ, wherein 0<x≤2; e.g., TiO₂), and/or aluminum oxide (e.g., AlOₓ, wherein 0<x≤2; e.g., Al₂O₃). The first light conversion layer QDL1, the second light conversion layer QDL2, and the light transmitting layer TPL may be encapsulated by the first capping layer CAP1, the second capping layer CAP2, and the third capping layer CAP3.

A fifth organic film 213 may be located or provided on the third capping layer CAP3. A plurality of color filters CF1, CF2, and CF3 may be located or provided on the fifth organic film 213. The plurality of color filters CF1, CF2 and CF3 may include first color filters CF1, second color filters CF2, and third color filters CF3.

The first color filter CF1 in the first sub-pixel SPX1 may transmit the first light (e.g., light in the red wavelength band) and may absorb or block the third light (e.g., light in the blue wavelength band). Therefore, the first color filter CF1 may transmit the first light (e.g., light in the red wavelength band) converted by the first light conversion layer QDL1 among the third light (e.g., light in the blue wavelength band) emitted from the light emitting element LE and may absorb or block the third light (e.g., light in the blue wavelength band) that is not converted by the first light conversion layer QDL1. Accordingly, the first sub-pixel SPX1 may emit the first light (e.g., light in the red wavelength band).

The second color filter CF2 in the second sub-pixel SPX2 may transmit the second light (e.g., light in the green wavelength band) and may absorb or block the third light (e.g., light in the blue wavelength band). Therefore, the second color filter CF2 may transmit the second light (e.g., light in the green wavelength band) converted by the first light conversion layer QDL1 among the third light (e.g., light in the blue wavelength band) emitted from the light emitting element LE and may absorb or block the third light (e.g., light in the blue wavelength band) that is not converted by the first light conversion layer QDL1. Accordingly, the second sub-pixel SPX2 may emit the second light (e.g., light in the green wavelength band).

The third color filter CF3 in the third sub-pixel SPX3 may transmit the third light (e.g., light in the blue wavelength band). Accordingly, the third color filter CF3 may transmit the third light (e.g., light in the blue wavelength band) passing through the light transmitting layer TPL and emitted from the light emitting element LE. Accordingly, the third sub-pixel SPX3 may emit the third light (e.g., light in the blue wavelength band).

The first color filter CF1, the second color filter CF2, and the third color filter CF3 overlapping in the third direction DR3 may overlap the light blocking layer BM in the third direction DR3.

A sixth organic film 214 for planarization may be located or provided on the plurality of color filters CF1, CF2, and CF3.

The fifth organic film 213 and the sixth organic film 214 may include an acryl resin, an epoxy resin, a phenolic resin, a polyamide resin, a polyimide resin, and/or the like.

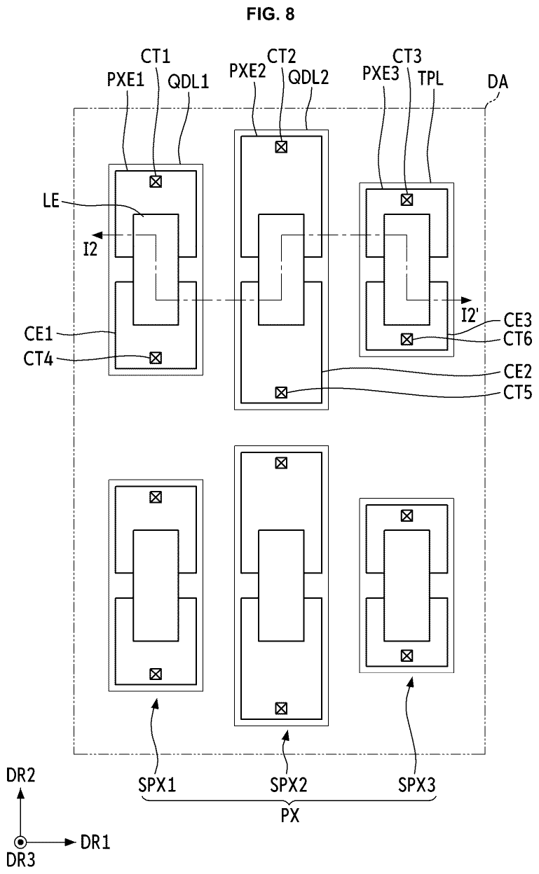

FIG. 8 is a layout view illustrating pixels of a display area according to one or more embodiments.

The embodiment of FIG. 8 is different from the embodiment of FIG. 5 in that the light emitting element LE is located or provided on the pixel electrode PXE1/PXE2/PXE3 and the common electrode CE1/CE2/CE3 in each of the first sub-pixel SPX1, the second sub-pixel SPX2, and the third sub-pixel SPX3. In the embodiment of FIG. 8, redundant description of parts that is described in the embodiment of FIG. 5 may not be provided.

Referring to FIG. 8, the pixel electrode PXE1/PXE2/PXE3 and the common electrode CE1/CE2/CE3 may be arranged or provided in the second direction DR2 in each of the first sub-pixel SPX1, the second sub-pixel SPX2, and the third sub-pixel SPX3. The pixel electrodes PXE1, PXE2, and PXE3 and the common electrodes CE1, CE2, and CE3 may each have a rectangular shape (e.g., a substantially rectangular shape) in plan view, but embodiments of the present disclosure are not limited thereto. Further, the area of the first pixel electrode PXE1 may be substantially the same as the area of the first common electrode CE1, the area of the second pixel electrode PXE2 may be substantially the same as the area of the second common electrode CE2, and the area of the third pixel electrode PXE3 may be substantially the same as the area of the third common electrode CE3, but embodiments of the present disclosure are not limited thereto.

If (e.g., when) the light conversion efficiency of the second light conversion layer QDL2 is less than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Further, the light transmitting layer TPL may directly transmit the light of the light emitting element LE, whereas the first light conversion layer QDL1 needs or is desired to convert the light, so that (e.g., such that) the area of the first pixel electrode PXE1 may be larger than the area of the third pixel electrode PXE3, and the area of the first common electrode CE1 may be larger than the area of the third common electrode CE3.

In the first sub-pixel SPX1, the first pixel electrode PXE1 and the first common electrode CE1 may be arranged or provided to be spaced and/or apart (e.g., spaced apart or separated) from each other in the second direction DR2. In the second sub-pixel SPX2, the second pixel electrode PXE2 and the second common electrode CE2 may be arranged or provided to be spaced and/or apart (e.g., spaced apart or separated) from each other in the second direction DR2. In the third sub-pixel SPX3, the third pixel electrode PXE3 and the third common electrode CE3 may be arranged or provided to be spaced and/or apart (e.g., spaced apart or separated) from each other in the second direction DR2.

The first common electrode CE1 may be connected to the second power line VSL to which the second driving voltage VSS is applied through a first common connection hole CT4. The second common electrode CE2 may be connected to the second power line VSL through a second common connection hole CT5. The third electrode CE3 may be connected to the second power line VSL through a third common connection hole CT6. Therefore, the second driving voltage VSS may be applied to each of the common electrodes CE1, CE2, and CE3.

In each of the first sub-pixel SPX1, the second sub-pixel SPX2, and the third sub-pixel SPX3, the light emitting electrode LE may be located or provided on the pixel electrode PXE1/PXE2/PXE3 and the common electrode CE1/CE2/CE3, so that (e.g., such that) the length of the light emitting element LE in the second direction DR2 may be longer than the length of the light emitting element LE in the first direction DR1.

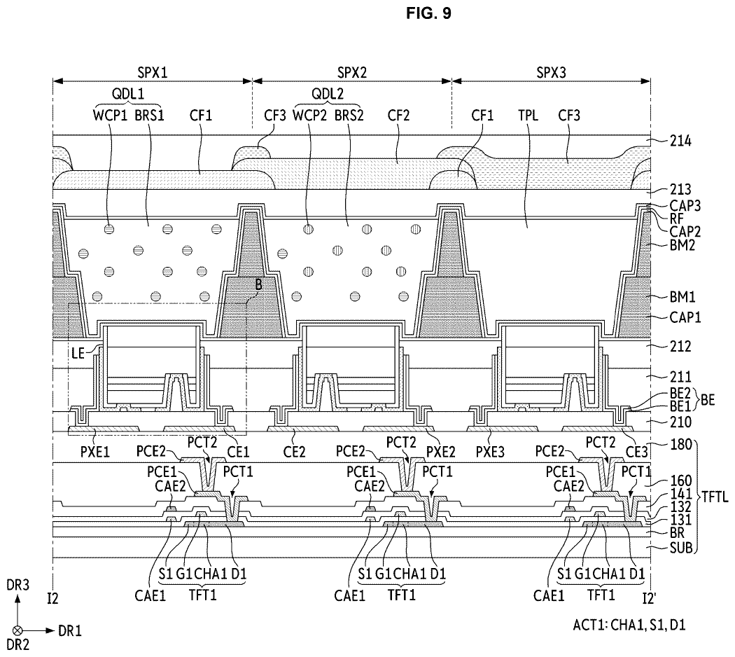

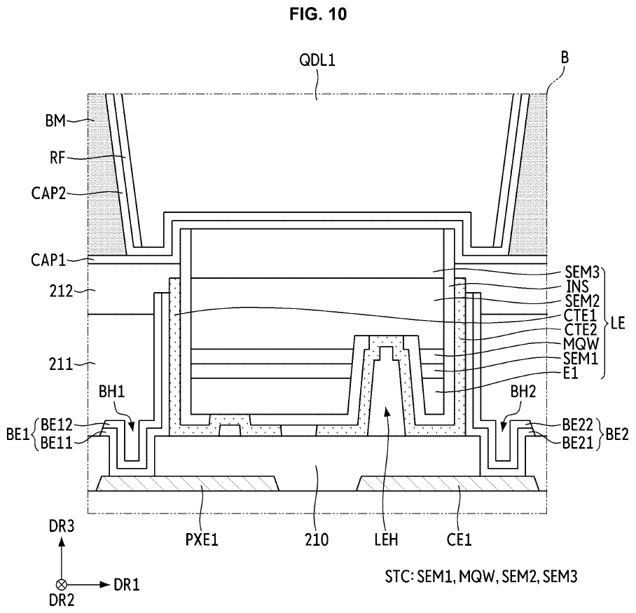

FIG. 9 is a cross-sectional view illustrating an example of a cross section of the display panel corresponding to the line 12-12′ of FIG. 8. FIG. 10 is a plan view illustrating an example of the area B of FIG. 9.

The embodiment of FIGS. 9 and 10 is different from the embodiment of FIGS. 6 and 7 in that the light emitting element LE is a flip type or kind micro LED. In the embodiment of FIGS. 9 and 10, redundant description of parts that is described in the embodiment of FIGS. 6 and 7 may not be provided.

Referring to FIGS. 9 and 10, a pixel electrode layer including the pixel electrodes PXE1, PXE2, and PXE3 and the common electrodes CE1, CE2, and CE3 may be located or provided on the second planarization film 180.

The light emitting element LE may be a flip type or kind micro LED. The flip type or kind micro LED refers to an LED in which contact electrodes CTE1 and CTE2 are formed or provided on one surface (e.g., the bottom surface) of the light emitting element LE.

The semiconductor stack STC of the light emitting element LE may further include a third semiconductor layer SEM3. The third semiconductor layer SEM3 may be located or provided on the second semiconductor layer SEM2.

The third semiconductor layer SEM3, which is a semiconductor material layer having an n-type or kind dopant concentration lower than a threshold value, may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type or kind dopant concentration lower than the threshold value.

Although it is illustrated in FIG. 10 that the protective film INS is located or provided on the side surfaces of the first semiconductor layer SEM1, the side surfaces of the active layer MQW, and the side surfaces of the second semiconductor layer SEM2 of the semiconductor stack STC and are not located or provided on the side surfaces of the third semiconductor layer SEM3, embodiments of the present disclosure are not limited thereto. For example, the protective film INS may be located or provided on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC.

A hole LEH that penetrates the conductive layer E1, the first semiconductor layer SEM1, and the active layer MQW of the light emitting element LE to expose the second semiconductor layer SEM2 may be formed or provided. The hole LEH may have a circular planar shape (e.g., a substantially circular planar shape) as illustrated in FIG. 2, but embodiments of the present disclosure are not limited thereto. For example, the hole LEH may have a polygonal planar shape (e.g., a substantially polygonal planar shape), such as an elliptical shape (e.g., a substantially elliptical shape) or a quadrilateral shape (e.g., a substantially quadrilateral shape).

Further, the protective film INS may be located or provided on the sidewall of the conductive layer E1, the sidewall of the first semiconductor layer SEM1, and the sidewall of the active layer MQW that are exposed in the hole LEH. The protective film INS may not cover the second semiconductor layer SEM2 in the hole LEH. Therefore, the second semiconductor layer SEM2 may be exposed without being covered by the protective film INS.

The first contact electrode CTE1 may be located or provided on at least one side surface of the semiconductor stack STC and at least one side surface and the bottom surface of the conductive layer E1. The first contact electrode CTE1 may be located or provided on the bottom surface of the conductive layer E1 that is exposed without being covered by the protective film INS. Therefore, the first contact electrode CTE1 may be electrically connected to the conductive layer E1.

The second contact electrode CTE2 may be located or provided on at least one side surface of the semiconductor stack STC and at least one side surface and the bottom surface of the conductive layer E1. At this time, the first contact electrode CTE1 may be located or provided on the first side surface of the semiconductor stack STC and the first side surface of the conductive layer E1, whereas the second contact electrode CTE2 may be located or provided on the second side surface of the semiconductor stack STC and the second side surface of the conductive layer E1.

The second contact electrode CTE2 may be located or provided on the protective film INS located or provided in the hole LEH and the second semiconductor layer SEM2 that is exposed without being covered by the protective film INS in the hole LEH. Therefore, the second contact electrode CTE2 may be electrically connected to the second semiconductor layer SEM2 in the hole LEH.

Although it is illustrated in FIGS. 9 and 10 that the first contact electrode CTE1 and the second contact electrode CTE2 of each of the light emitting elements LE are located or provided on the first organic film 210, embodiments of the present disclosure are not limited thereto. For example, the first organic film 210 may be located or provided on a part of the side surface and the bottom surface of the first contact electrode CTE1 and a part of the side surface and the bottom surface of the second contact electrode CTE2 of each of the light emitting elements LE. In one or more embodiments, the first organic film 210 may be located or provided on the side surfaces of the conductive layer E1 of each of the light emitting elements LE. In one or more embodiments, the first organic film 210 may be located or provided on the side surfaces of the first semiconductor layer SEM1, the side surfaces of the active layer MQW, and the side surfaces of the second semiconductor layer SEM2 of each of the light emitting elements LE. In this case, the first organic film 210 may be located or provided on a part of each of the side surfaces of the second semiconductor layer SEM2.

Each of the first contact electrode CTE1 and the second contact electrode CTE2 may be located or provided on three side surfaces of the semiconductor stack STC. For example, if (e.g., when) the semiconductor stack STC includes first to fourth side surfaces, the first contact electrode CTE1 may be located or provided on the first side surface, the second side surface, and the third side surface, and the second contact electrode CTE2 may be located or provided on the second side surface, the third side surface, and the fourth side surface.

The first connection electrode BE1 may connect the first contact electrode CTE1 of the light emitting element LE to the pixel electrode PXE1/PXE2/PXE3. The first connection electrode BE1 may be connected to the pixel electrode PXE1/PXE2/PXE3 exposed through a first connection hole BH1 penetrating the first organic film 210. Further, the first connection electrode BE1 may be located or provided on the top surface of the first organic film 210 and the first contact electrode CTE1.

The second connection electrode BE2 may connect the second contact electrode CTE2 of the light emitting element LE to the common electrode CE1/CE2/CE3. The second connection electrode BE2 may be connected to the common electrode CE1/CE2/CE3 exposed through a second connection hole BH2 penetrating the first organic film 210. Further, the second connection electrode BE2 may be located or provided on the top surface of the first organic film 210 and the second contact electrode CTE2.

Each of the first connection electrode BE1 and the second connection electrode BE2 may include any one selected from among molybdenum (Mo), aluminum (AI), chromium (Cr), gold (Au), titanium (Ti), nickel (Ni), neodymium (Nd), and copper (Cu). In one or more embodiments, each of the first connection electrode BE1 and the second connection electrode BE2 may include a transparent (e.g., substantially transparent) conductive (e.g., electrically conductive) material (TCO), such as indium tin oxide (ITO) and/or indium zinc oxide (IZO).

As illustrated in FIGS. 9 and 10, the conductive layer E1 of the light emitting element LE may be connected to the pixel electrode PXE1/PXE2/PXE3 through the first contact electrode CTE1 and the first connection electrode BE1. Further, the second semiconductor layer SEM2 of the light emitting element LE may be connected to the common electrode CE1/CE2/CE3 through the second connection electrode BE2 and the second contact electrode CTE2 formed or provided in the hole LEH.

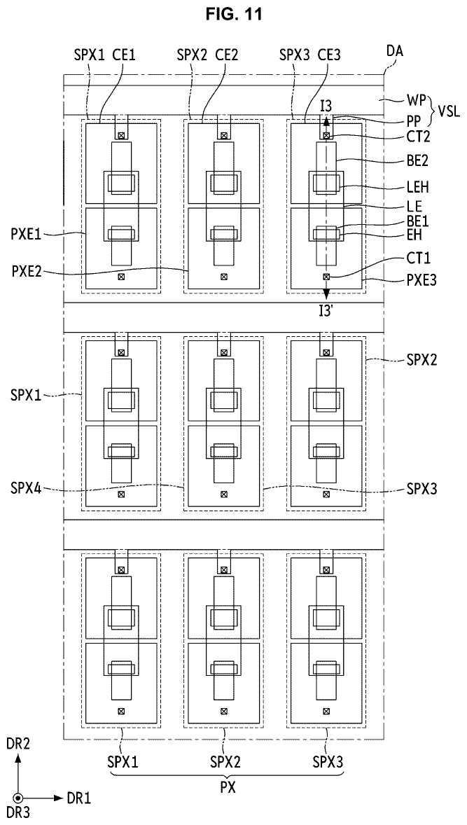

FIG. 11 is a layout view illustrating pixels of a display area according to one or more embodiments.

The embodiment of FIG. 11 is different from the embodiment of FIG. 5 in that the light emitting element LE is located or provided on the pixel electrode PXE1/PXE2/PXE3 and the common electrode CE1/CE2/CE3 in each of the first sub-pixel SPX1, the second sub-pixel SPX2, and the third sub-pixel SPX3. In the embodiment of FIG. 11, redundant description of parts that is described in the embodiment of FIG. 5 may not be provided.

Referring to FIG. 11, the pixel electrode PXE1/PXE2/PXE3 and the common electrode CE1/CE2/CE3 may be arranged or provided in the second direction DR2 in each of the first sub-pixel SPX1, the second sub-pixel SPX2, and the third sub-pixel SPX3. The first pixel electrode PXE1 and the first common electrode CE1 may be located or provided to be spaced and/or apart (e.g., spaced apart or separated) from each other. The second pixel electrode PXE2 and the second common electrode CE2 may be located or provided to be spaced and/or apart (e.g., spaced apart or separated) from each other. The third pixel electrode PXE3 and the third common electrode CE3 may be located or provided to be spaced and/or apart (e.g., spaced apart or separated) from each other.

Each of the first pixel electrode PXE1, the second pixel electrode PXE2, the third pixel electrode PXE3, the first common electrode CE1, the second common electrode CE2, and the third common electrode CE3 may have a rectangular planar shape (e.g., a substantially rectangular planar shape), but embodiments of the present disclosure are not limited thereto. Further, the area of the first pixel electrode PXE1 may be substantially the same as the area of the first common electrode CE1, the area of the second pixel electrode PXE2 may be substantially the same as the area of the second common electrode CE2, and the area of the third pixel electrode PXE3 may be substantially the same as the area of the third common electrode CE3, but embodiments of the present disclosure are not limited thereto.

The first common electrode CE1 may be connected to the second power line VSL to which the second driving voltage VSS is applied through a first common connection hole CT4. The second common electrode CE2 may be connected to the second power line VSL through a second common connection hole CT5. The third electrode CE3 may be connected to the second power line VSL through a third common connection hole CT6. Accordingly, the second driving voltage VSS may be applied to each of the common electrodes CE1, CE2, and CE3.

The first connection electrode BE1 may be connected to the pixel electrode PXE1/PXE2/PXE3 and the first electrode E1 of the light emitting element LE. The first connection electrode BE1 may overlap at least a part of the first electrode E1. The first connection electrode BE1 may overlap at least a part of the pixel electrode PXE1/PXE2/PXE3.

The second connection electrode BE2 may be connected to the common electrode CE1/CE2/CE3 and the second electrode E2 of the light emitting element LE. The second connection electrode BE2 may overlap at least a part of the second electrode E2. The second connection electrode BE2 may overlap at least a part of the common electrode CE1/CE2/CE3.

Each of the second power lines VSL may include a line portion WP extending in the first direction DR1 and a protrusion PP that protrudes from the line portion WP in the second direction DR2 and overlaps the second pixel connection hole CT2.

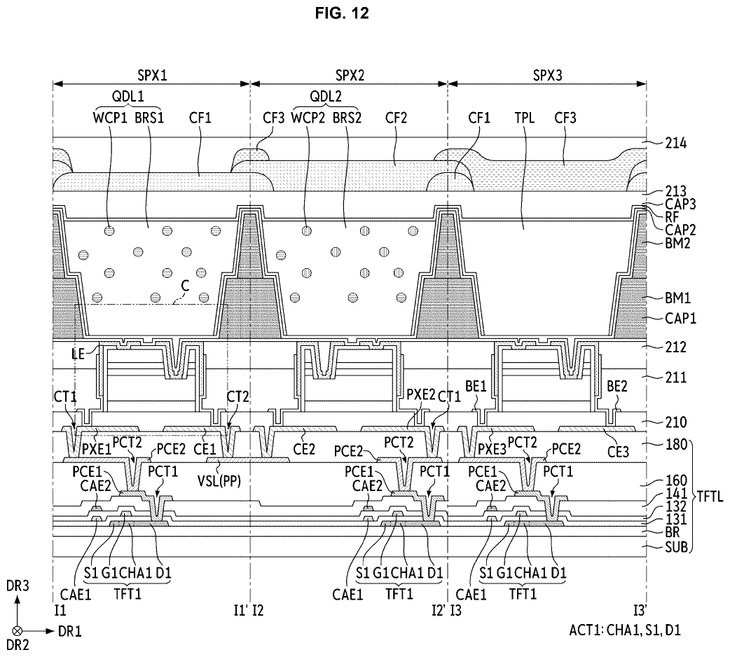

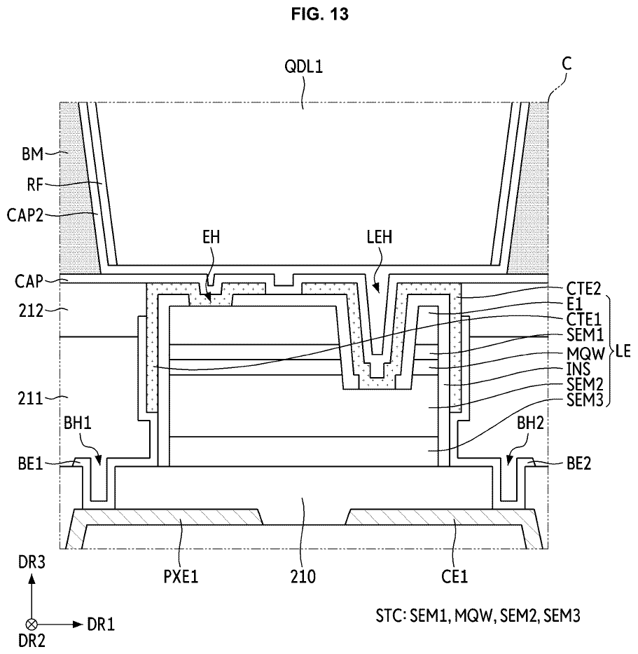

FIG. 12 is a cross-sectional view illustrating an example of a cross section of the display panel corresponding to the line 13-13′ of FIG. 11. FIG. 13 is a cross-sectional view illustrating an example of the area C of FIG. 12.

The embodiment of FIGS. 12 and 13 is different from the embodiment of FIGS. 6 and 7 in that the light emitting element LE is a lateral type or kind micro LED. In the embodiments of FIGS. 12 and 13, redundant description of the parts that is described in the embodiment of FIGS. 6 and 7 may not be provided.

Referring to FIGS. 12 and 13, a pixel electrode layer including the pixel electrodes PXE1, PXE2, and PXE3 and the common electrodes CE1, CE2, and CE3 may be located or provided on the second planarization film 180. The pixel electrodes PXE1, PXE2, and PXE3 and the common electrodes CE1, CE2, and CE3 may be spaced and/or apart (e.g., spaced apart or separated) from each other.

The pixel electrode PXE1/PXE2/PXE3 may be connected to the second source connection electrode PCE2 through the pixel connection hole CT1/CT2/CT3 penetrating the second planarization film 180. The pixel electrode PXE1/PXE2/PXE3 may be connected to the first source region S1 or the first drain region D1 of the thin film transistor TFT1 through the first source connection electrode PCE1 and the second source connection electrode PCE2. Accordingly, the voltage controlled or selected by the thin film transistor TFT1 may be applied to each of the pixel electrode PXE1/PXE2/PXE3.

The common electrode CE1/CE2/CE3 may be connected to the second power line VSL through the common connection hole CT4/CT5/CT6 penetrating the second planarization film 180. Accordingly, the second driving voltage VSS (see FIG. 3) may be applied to each of the common electrode CE1/CE2/CE3.

If (e.g., when) the pixel electrode layer includes a metal material having high reflectivity, among the light emitted from an active layer MQW of the light emitting element LE, the light traveling in a downward direction with respect to the light emitting element LE may be reflected from the pixel electrode PXE1/PXE2/PXE3 and the common electrode CE1/CE2/CE3 to travel in an upward direction with respect to the light emitting element LE. Accordingly, because light loss from the light emitting element LE may be reduced, the light efficiency of the light emitting element LE may be increased or enhanced.

The first organic film 210 may be located or provided on the pixel electrodes PXE1, PXE2, and PXE3 and the common electrodes CE1, CE2, and CE3 in the respective sub-pixels SPX1, SPX2, and SPX3. The first organic film 210 may serve to temporarily fix or adhere the light emitting element LE during the process of transferring the light emitting element LE to the display panel 100.

The light emitting element LE in each of the sub-pixels SPX1, SPX2, and SPX3 may be located or provided on the first organic film 210. The light emitting element LE may be exemplified as a lateral type or kind micro LED in which both (e.g., simultaneously) the first electrode E1 and the second electrode E2 protrude from the top surface of the light emitting element LE and the current flows in the lateral direction.

The semiconductor stack STC of the light emitting element LE may further include a third semiconductor layer SEM3. The third semiconductor layer SEM3 may be located or provided on the first organic film 210, and the second semiconductor layer SEM2 may be located or provided on the third semiconductor layer SEM3.

The third semiconductor layer SEM3, which is a semiconductor material layer having an n-type or kind dopant concentration lower than a threshold value, may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type or kind dopant concentration lower than the threshold value.

Although it is illustrated in FIG. 13 that the protective film INS is located or provided on the side surfaces of the first semiconductor layer SEM1, the side surfaces of the active layer MQW, and the side surfaces of the second semiconductor layer SEM2 of the semiconductor stack STC and are not located or provided on the side surfaces of the third semiconductor layer SEM3, embodiments of the present disclosure are not limited thereto. For example, the protective film INS may be located or provided on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC.

A hole LEH that penetrates the conductive layer E1, the first semiconductor layer SEM1, and the active layer MQW of the light emitting element LE to expose the second semiconductor layer SEM2 may be formed or provided. The hole LEH may have a circular planar shape (e.g., a substantially circular planar shape) as illustrated in FIG. 2, but embodiments of the present disclosure are not limited thereto. For example, the hole LEH may have a polygonal planar shape (e.g., a substantially polygonal planar shape), such as an elliptical shape (e.g., a substantially elliptical shape) and/or a quadrilateral shape (e.g., a substantially quadrilateral shape).

Further, the protective film INS may be located or provided on the sidewall of the conductive layer E1, the sidewall of the first semiconductor layer SEM1, and the sidewall of the active layer MQW that are exposed in the hole LEH. The protective film INS may not cover the second semiconductor layer SEM2 in the hole LEH. Therefore, the second semiconductor layer SEM2 may be exposed without being covered by the protective film INS.

The first contact electrode CTE1 may be located or provided on at least one side surface of the semiconductor stack STC and at least one side surface and the bottom surface of the conductive layer E1. The first contact electrode CTE1 may be located or provided on the bottom surface of the conductive layer E1 that is exposed without being covered by the protective film INS. Therefore, the first contact electrode CTE1 may be electrically connected to the conductive layer E1.

The second contact electrode CTE2 may be located or provided on at least one side surface of the semiconductor stack STC and at least one side surface and the bottom surface of the conductive layer E1. At this time, the first contact electrode CTE1 may be located or provided on the first side surface of the semiconductor stack STC and the first side surface of the conductive layer E1, whereas the second contact electrode CTE2 may be located or provided on the second side surface of the semiconductor stack STC and the second side surface of the conductive layer E1.

The second contact electrode CTE2 may be located or provided on the protective film INS located or provided in the hole LEH and the second semiconductor layer SEM2 that is exposed without being covered by the protective film INS in the hole LEH. Therefore, the second contact electrode CTE2 may be electrically connected to the second semiconductor layer SEM2 in the hole LEH.

Although it is illustrated in FIGS. 12 and 13 that the third semiconductor layer SEM3 of each of the light emitting elements LE is located or provided on the first organic film 210, embodiments of the present disclosure are not limited thereto. For example, the first organic film 210 may be located or provided on the side surfaces of the third semiconductor layer SEM3 of each of the light emitting elements LE. In one or more embodiments, the first organic film 210 may be located or provided on a part of each of the side surfaces of the second semiconductor layer SEM2 of each of the light emitting elements LE.

Each of the first contact electrode CTE1 and the second contact electrode CTE2 may be located or provided on three side surfaces of the semiconductor stack STC. For example, if (e.g., when) the semiconductor stack STC includes first to fourth side surfaces, the first contact electrode CTE1 may be located or provided on the first side surface, the second side surface, and the third side surface, and the second contact electrode CTE2 may be located or provided on the second side surface, the third side surface, and the fourth side surface.

The first connection electrode BE1 may connect the first contact electrode CTE1 of the light emitting element LE to the pixel electrode PXE1/PXE2/PXE3. The first connection electrode BE1 may be connected to the pixel electrode PXE1/PXE2/PXE3 exposed through the first connection hole BH1 penetrating the first organic film 210. Further, the first connection electrode BE1 may be located or provided on the top surface of the first organic film 210, the protective film INS located or provided on the side surface of the second semiconductor layer SEM2, and the side surface of the third semiconductor layer SEM3, and the first contact electrode CTE1.

The second connection electrode BE2 may connect the second contact electrode CTE2 of the light emitting element LE to the common electrode CE1/CE2/CE3. The second connection electrode BE2 may be connected to the common electrode CE1/CE2/CE3 exposed through the second connection hole BH2 penetrating the first organic film 210. Further, the second connection electrode BE2 may be located or provided on the top surface of the first organic film 210, the protective film INS on the side surface of the second semiconductor layer SEM2, and the side surface of the third semiconductor layer SEM3, and the second contact electrode CTE2.

Each of the first connection electrode BE1 and the second connection electrode BE2 may include any one selected from among molybdenum (Mo), aluminum (Al), chromium (Cr), gold (Au), titanium (Ti), nickel (Ni), neodymium (Nd), and copper (Cu). In one or more embodiments, each of the first connection electrode BE1 and the second connection electrode BE2 may include a transparent (e.g., substantially transparent) conductive (e.g., electrically conductive) material (TCO), such as indium tin oxide (ITO) and/or indium zinc oxide (IZO).

As illustrated in FIGS. 12 and 13, the conductive layer E1 of the light emitting element LE may be connected to the pixel electrode PXE1/PXE2/PXE3 through the first contact electrode CTE1 and the first connection electrode BE1. Further, the second semiconductor layer SEM2 of the light emitting element LE may be connected to the common electrode CE1/CE2/CE3 through the second connection electrode BE2 and the second contact electrode CTE2 formed or provided in the hole LEH.

The first organic film 210, the third organic film 211, and the fourth organic film 212 may serve to temporarily fix or adhere the plurality of light emitting elements LE in order to prevent them from tilting and/or falling (or to reduce a degree to or occurrence of which the plurality of light emitting elements LE tilts and/or falls) during the process of transferring the plurality of light emitting elements LE to the display panel 100. To this end, the first organic film 210, the third organic film 211, and the fourth organic film 212 may include an organic film composition for adhesion.

The adhesiveness of the organic film composition for adhesion exposed to the air may deteriorate as the curing rate of the organic film composition for adhesion increases over time. If (e.g., when) the curing rate of the organic film composition for adhesion increases before the plurality of light emitting elements LE are transferred to the display panel 100, it may be difficult to fix the light emitting element LE to the display panel 100. For example, it is necessary or desired to prevent or reduce an increase in the curing rate before the plurality of light emitting elements LE are fixed to the display panel 100.

As described herein, in the organic film composition for adhesion of the organic film 210 according to one or more embodiments, the content (e.g., amount) of the monomer increases and the content (e.g., amount) of the photoinitiator decreases, so that (e.g., such that) the fluidity and adhesiveness of the organic film composition for adhesion may be improved or enhanced. As a result, the increase in the curing rate of the organic film 210 may be prevented or reduced before the plurality of light emitting elements LE are fixed to the display panel 100, so that (e.g., such that) the fixability of the light emitting element LE transferred to the display panel 100 may be improved or enhanced.

The organic film composition for adhesion may maintain high adhesiveness and fluidity due to its high stability even if (e.g., when) it is exposed to the air for a long period of time. Even if (e.g., when) the organic film composition for adhesion is exposed to the air for a long period of time during the process of transferring the plurality of light emitting elements LE to the display panel 100, the organic film composition for adhesion is not cured, so that (e.g., such that) the light emitting element LE may be easily or suitably fixed.

The organic film composition for adhesion may include an organic film composition for adhesion including a monomer represented by Chemical Formula 1; a reactive unsaturated compound represented by Chemical Formula 2; a photoinitiator; and a solvent.

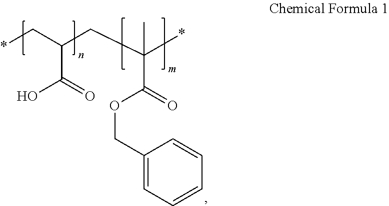

where n and m are integers.

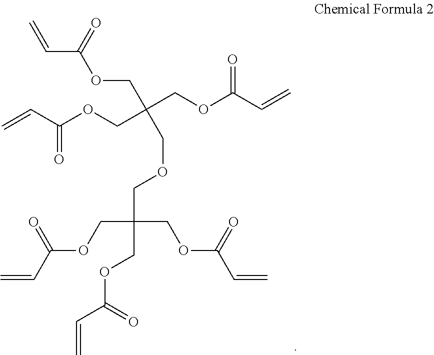 [SMILES: C=CC(=O)OCC(COCC(COC(=O)C=C)(COC(=O)C=C)COC(=O)C=C)(COC(=O)C=C)COC(=O)C=C]

The organic film composition for adhesion may include 25 parts to 50 parts by weight of the monomer represented by the Chemical Formula 1, 5 parts to 10 parts by weight of the reactive unsaturated compound, 0.25 parts to 5 parts by weight of the photoinitiator, and 40 parts to 70 parts by weight of the solvent with respect to (e.g., based on) 100 parts by weight of the organic film composition for adhesion. If (e.g., when) the monomer represented by the Chemical Formula 1 is present in an amount of less than 25 parts by weight, the fluidity and adhesiveness of the organic film composition for adhesion may deteriorate or reduce. If (e.g., when) the photoinitiator is present in an amount of greater than 5 parts by weight, the fluidity of the organic film composition for adhesion may deteriorate or reduce.

The photoinitiator may include at least one of an oxime-based compound, an acetophenone-based compound, a benzophenone-based compound, a thioxanthone-based compound, a benzoin-based compound, a triazine-based compound, a carbazole-based compound, a diketone-based compound, a sulfonium borate-based compound, a diazo-based compound, an imidazole-based compound, or a biimidazole-based compound. For example, the photoinitiator may be an oxime-based compound.

The oxime-based compound may include at least one of 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, 2-dimethylamino-2-(4-methylbenzyl)-1-(4-morpholin-4-yl-phenyl)-butan-1-one, 1-(4-phenylsulfanylphenyl)-butane-1,2-dione2-oxime-O-benzoate, 1-(4-phenylsulfanylphenyl)-octane-1,2-dione2-oxime-O-benzoate, 1-(4-phenylsulfanylphenyl)-octane-1-one oxime-O-acetate, 1-(4-phenylsulfanylphenyl)-butane-1-one oxime-O-acetate, 1-(4-methylsulfanyl-phenyl)-butane-1-one oxime-O-acetate, hydroxyimino-(4-methylsulfanyl-phenyl)-acetate ethyl ester-O-acetate, or hydroxyimino-(4-methylsulfanyl-phenyl)-acetate ethyl ester-O-benzoate.

The acetophenone-based compound may include at least one of 2,2′-diethoxy acetophenone, 2,2′-dibuthoxy acetophenone, 2-hydroxy-2-methylpropiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, or 2-benzyl-2-dimethylamino-1-(4-morpholinophenyl)-butan-1-one.

The benzophenone-based compound may include at least one of benzophenone, benzoyl benzoate, methyl benzoyl benzoate, 4-phenyl benzophenone, hydroxy benzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, or 3,3′-dimethyl-2-methoxybenzophenone.

The thioxanthone-based compound may include at least one of thioxanthone, 2-chlorothioxanthone, 2-methylthioxanthone, isopropyl thioxanthone, 2,4-diethyl thioxanthone, 2,4-diisopropyl thioxanthone, or 2-chlorothioxanthone.

The benzoin-based compound may include at least one of benzoin, benzoin methyl ether, benzoin ethyl ether, benzoin isopropyl ether, benzoin isobutyl ether, or benzyldimethyl ketal.

The triazine-based compound may include at least one of 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-s(trichloromethyl)-s-triazine, 2-4-trichloromethyl(piperonyl)-6-triazine, or 2-4-trichloromethyl(4′-methoxystyryl)-6-triazine.

The organic film composition for adhesion may further include an ionic initiator.

The ionic initiator may generate ionic species or Lewis acid by irradiation of an active energy ray, such as visible light, ultraviolet light, X-rays, and/or electron beams, thereby initiating a polymerization reaction of an ion polymerizable compound.

The ionic initiator may include at least one of a phosphorus anion ([(Rf)ₙPF_{6-n]}⁻), a hexafluorophosphate anion (PF₆⁻), a hexafluoroantimonate anion (SbF₆⁻), a pentafluorohydroxyantimonate anion (SbF₅(OH)⁻), a hexafluoroacetate anion (AsF₆⁻), a tetrafluoroborate anion (BF₄⁻), or a tetrakis(pentafluorophenyl)borate anion (B(C₆F₅)₄⁻).

For example, the ionic initiator may be a hexafluorophosphate anion.

The solvent may include at least one of methanol, ethanol, dichloroethyl ether, n-butyl ether, diisoamyl ether, methylphenyl ether, tetrahydrofuran, ethylene glycol monomethyl ether, ethylene glycol monoethyl ether, methyl cellosolve acetate, ethyl cellosolve acetate, diethyl cellosolve acetate, methylethyl carbitol, diethyl carbitol, diethylene glycol monomethyl ether, diethylene glycol monoethyl ether, diethylene glycol dimethyl ether, diethylene glycol methylethyl ether, diethylene glycol diethyl ether, propylene glycol methyl ether acetate, propylene glycol propyl ether acetate, toluene, xylene, methyl ethyl ketone, cyclohexanone, 4-hydroxy-4-methyl-2-pentanone, methyl-n-propyl ketone, methyl-n-butyl ketone, methyl-n-amyl ketone, 2-heptanone, ethyl acetate, n-butyl acetate, isobutyl acetate, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, ethyl ethoxyacetate, methyl 3-oxypropionate, ethyl 3-oxypropionate, methyl 3-methoxypropionate, ethyl 3-methoxypropionate, ethyl 3-ethoxypropionate, methyl 3-ethoxypropionate, methyl 2-oxypropionate, ethyl 2-oxypropionate, propyl 2-oxypropionate, methyl 2-methoxypropionate, ethyl 2-methoxypropionate, ethyl 2-ethoxypropionate, methyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate, ethyl 2-hydroxypropionate, ethyl 2-hydroxy-2-methylpropionate, ethyl hydroxyacetate, methyl 2-hydroxy-3-methylbutanoate, ethyl pyruvate, N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, or phenyl cellosolve acetate. For example, the solvent may be methyl 3-methoxy propionate.

One or more embodiments of the present disclosure will be described in more detail through the following embodiments, but the following embodiments are only for the purpose of description and not intended to limit the scope of the present disclosure.

### 1. Preparation of Organic Film Composition for Adhesion

### Embodiment 1

First, an organic film composition for adhesion was prepared by mixing 50 parts by weight of the compound of Chemical Formula 1 as the monomer, 5 parts by weight of the compound of Chemical Formula 2 as the reactive unsaturated compound, 2 parts by weight of the compound of Chemical Formula 3 as the photoinitiator, 43 parts by weight of methyl 3-methoxypropionate as the solvent, and a small amount of a hexafluorophosphate anion as the ionic initiator.

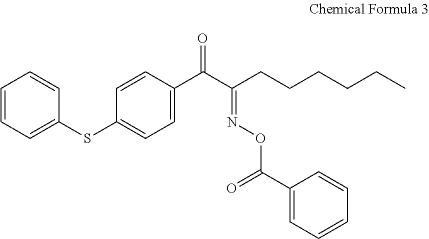 [SMILES: CCCCCC/C(=N\OC(=O)c1ccccc1)C(=O)c1ccc(Sc2ccccc2)cc1]

### Comparative Example 1

An organic film composition for adhesion was prepared in substantially the same manner as that in Embodiment 1, except that 10 parts by weight of the compound of Chemical Formula 1 was used as the monomer, 5 parts by weight of the compound of Chemical Formula 3 was used as the photoinitiator, and 80 parts by weight of methyl 3-methoxypropionate was used as the solvent.

Table 1 shows the content (e.g., amount) of each material in the case of preparing the organic film compositions for adhesion of Embodiment 1 and Comparative Example 1.

TABLE 1

| | | Reactive | | | |
|---|---|---|---|---|---|
| Content (e.g., amount) | | Unsaturated | | | Ionic |
| (parts by weight) | Monomer | Compound | Photoinitiator | Solvent | Initiator |
| Embodiment 1 | 50 | 5 | 2 | 43 | Small |
| | | | | | amount |
| Comparative | 10 | 5 | 5 | 80 | Small |
| Example 1 | | | | | amount |

### Evaluation

### 1. Curing Rate of Organic Film Composition for Adhesion

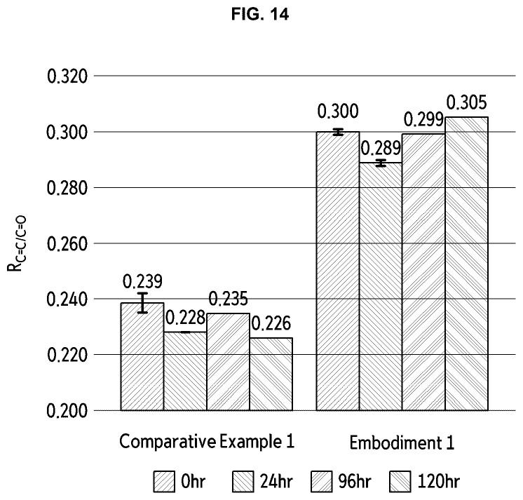

The curing rates of the organic film compositions for adhesion prepared in Embodiment 1 and Comparative Example 1 were measured, and the results are shown in FIG. 14.

FIG. 14 is a graph illustrating the curing rate of an organic film composition for adhesion according to one or more embodiments of the present disclosure.

For example, FIG. 14 is a graph illustrating a ratio (R_{C═C}/_{C═O}) of a C═C bond peak intensity to a C═O bond peak intensity which is measured over time using Fourier Transform Infrared Spectroscopy (FT-IR).

The curing rate may be obtained by Equation 1.

$${R}_{C = C / C = O} = {I}_{C = C} / {I}_{C = O} \qquad Equation 1$$

In Equation 1, the I_{C═C} is the C═C bond peak intensity in the infrared spectral spectrum, and the I_{C═O} is the C═O bond peak intensity in the infrared spectral spectrum.

If (e.g., when) the organic film composition for adhesion is cured, the carbon-carbon double bonds are converted to carbon-carbon single bonds. As the curing rate increases, the ratio of carbon-carbon double bonds may decrease. A higher R_{C═C/C═O} value denotes a lower curing rate, and a lower R_{C═C/C═O} value denotes a higher curing rate.

According to the results as shown in FIG. 14, it may be confirmed that the R_{C═C}/_{C═O} is higher in Embodiment 1 than in Comparative Example 1. This indicates that the ratio of carbon-carbon double bonds of Embodiment 1 is higher than that of Comparative Example 1. For example, the curing rate of Embodiment 1 is lower than that of Comparative Example 1.

It may be confirmed that the R_{C═C}/_{C═O} value of Embodiment 1 is maintained at a similar level even after 120 hours. This indicates that the organic film composition for adhesion of Embodiment 1 may maintain fluidity without being cured even after time has elapsed. If (e.g., when) the organic film composition for adhesion of Embodiment 1, which is capable of maintaining high fluidity, is utilized to fix the light emitting element LE to the display panel 100 of the display device, there may be no influence from the stagnation time of the process.

The R_{C═C/C═O} of the organic film composition for adhesion of the present disclosure and the organic film utilizing the organic film composition for adhesion may be 0.28 or more.

### 2. Adhesion Force of Organic Film Composition for Adhesion

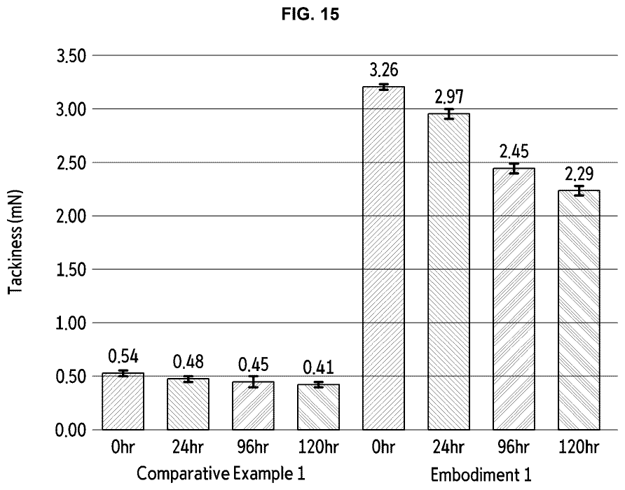

The adhesion forces of the organic film compositions for adhesion prepared in Embodiment 1 and Comparative Example 1 were measured, and the results are shown in FIG. 15.

The adhesion force was measured using a bio-indenter from Anton Paar. A ruby ball having a diameter of 500 μm was used as a tip, and the loading speed of the tip was measured at 6 mN/min. When the measurement sample was pressurized with a force of 1 mN using the tip and maintained for about 1 minute and then decompressed, the force (the change in the force applied to the tip when the sample attached to the tip is separated from the tip) generated by the adhesiveness of the sample was measured to measure the adhesion force of the sample.

FIG. 15 is a graph obtained by measuring the adhesion force of an organic film composition for adhesion according to one or more embodiments of the present disclosure.

For example, FIG. 15 is a graph obtained by measuring the adhesion forces of Embodiment 1 and Comparative Example 1 over time.

According to the results as shown in FIG. 15, it may be confirmed that the adhesion force of Comparative Example 1 was a maximum of 0.54 mN and decreased to 0.41 mN after 120 hours. On the other hand, it may be confirmed that the adhesion force of Embodiment 1 was a maximum of 3.26 mN and the high adhesion force of 2.29 mN was maintained even after 120 hours. This indicates that the adhesion force of Embodiment 1 is higher than that of Comparative Example 1. If (e.g., when) the organic film composition for adhesion of Embodiment 1, which is capable of maintaining high adhesiveness, is used to fix the light emitting element LE to the display panel 100 of the display device, the fixability of the light emitting element LE may be improved or enhanced.

The adhesion force of the organic film composition for adhesion of the present disclosure and the organic film utilizing the organic film composition for adhesion may be 2.22 mN or more.

### 3. Modulus of Organic Film Composition for Adhesion

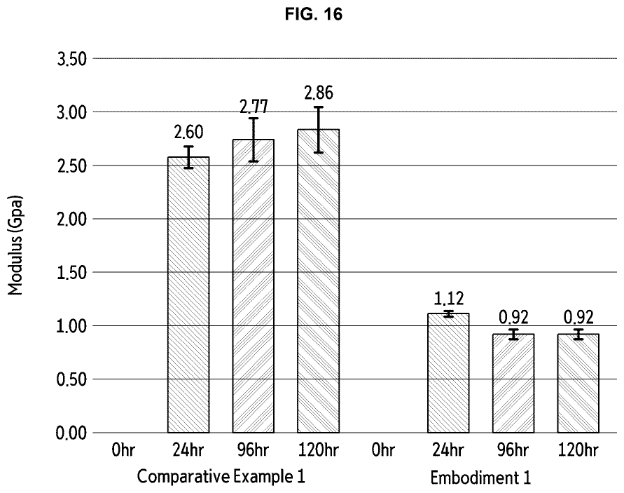

The moduli of the organic film compositions for adhesion prepared in Embodiment 1 and Comparative Example 1 were measured, and the results are shown in FIG. 16.

The modulus was measured using a nanoindenter from Anton Paar. A Berkovich tip was used as the tip, and the loading speed of the tip was measured at 0.5 mN/min. The modulus may be measured by analyzing the load-displacement curve obtained by applying and removing a force of 0.05 mN to the sample surface for 60 seconds using the tip of the indenter. It may be observed that the surface curing rate increases as the modulus becomes greater.

FIG. 16 is a graph obtained by measuring the modulus of an organic film composition for adhesion according to one or more embodiments of the present disclosure.

For example, FIG. 16 is a graph obtained by measuring moduli of Embodiment 1 and Comparative Example 1 over time.

According to the results as shown in FIG. 16, it may be confirmed that the modulus of Comparative Example 1 increases from 2.60 GPa to 2.86 GPa over time. On the other hand, it may be confirmed that the modulus of Embodiment 1 is maintained between 0.92 GPa and 1.12 GPa. This indicates that the surface curing rate of Embodiment 1 is less than the surface curing rate of Comparative Example 1. If (e.g., when) the organic film composition for adhesion of Comparative Example 1 is used to fix the light emitting element LE to the display panel 100 of the display device, the bonding rate may be reduced due to the high surface curing rate, which may lower the fixing rate of the light emitting element LE. On the other hand, if (e.g., when) the organic film composition for adhesion of Embodiment 1 having a low surface curing rate is used to fix the light emitting element LE to the display panel 100 of the display device, the fixability of the light emitting element LE may be improved. Further, because the fluidity of the organic film composition for adhesion of Embodiment 1 is greater than that of the organic film composition for adhesion of Comparative Example 1, the moduli of the organic film composition for adhesion of the present disclosure and the organic film using the organic film composition for adhesion may be 1.5 GPa or less.

### 4. Bonding Rate of Organic Film Composition for Adhesion

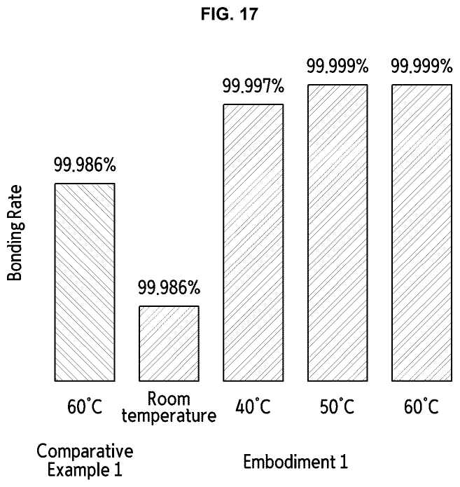

The bonding rates of the organic film compositions for adhesion prepared in Embodiment 1 and Comparative Example 1 according to temperature were measured, and the results are shown in FIG. 17.

FIG. 17 is a graph obtained by measuring the bonding rate according to the temperature of the organic film composition for adhesion according to one or more embodiments of the present disclosure.

According to the results as shown in FIG. 17, in Comparative Example 1, the bonding rate was 99.986% at a temperature of 60° C. In Embodiment 1, the bonding rate was 99.999% at 50° C. or higher.

For example, in Embodiment 1, the bonding rate of 99.997% was achieved at a temperature of 40° C. This indicates that a higher bonding rate is achieved even at a temperature lower than that in Comparative Example 1. Embodiment 1 may achieve a higher bonding rate than Comparative Example 1 even if (e.g., when) the process is performed at a low temperature, and thus is easily utilized for a low-temperature process.

If (e.g., when) the organic film composition for adhesion of Embodiment 1 is used to fix the light emitting element LE to the display panel 100 of the display device, the fixability of the light emitting element LE may be improved or enhanced with a high bonding rate even if (e.g., when) the process is performed at a low temperature of 40° C.

The bonding rate of the organic film composition for adhesion of the present disclosure and the organic film using the organic film composition for adhesion may be 99.99% or higher at a temperature of 40° C. or higher.

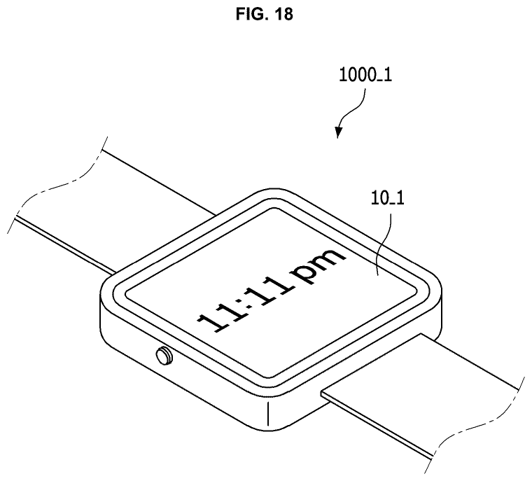

FIG. 18 illustrates a smart watch including a display device according to one or more embodiments. Referring to FIG. 18, a display device 10_1 according to one or more embodiments may be applied to a smart watch 1000_1 that is one of the smart devices.

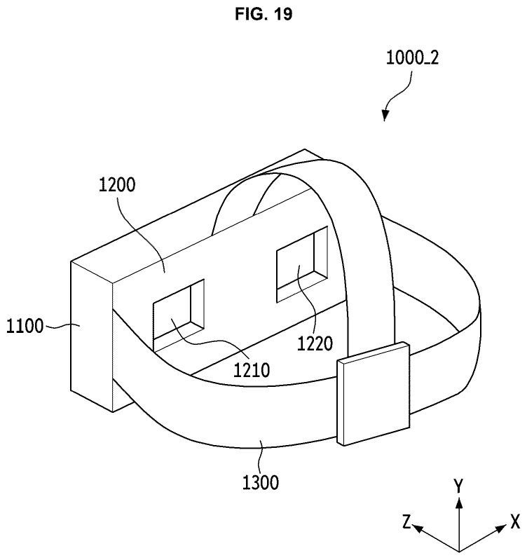

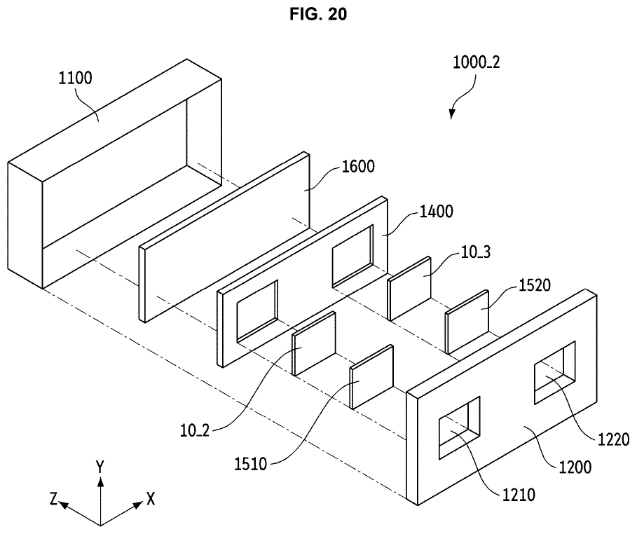

FIGS. 19 and 20 illustrate a virtual reality device including a display device according to one or more embodiments.

Referring to FIGS. 19 and 20, a head mounted display 1000_2 according to one or more embodiments may include a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 may provide an image to the user's left eye, and the second display device 10_3 may provide an image to the user's right eye. Because each of the first display device 10_2 and the second display device 10_3 is substantially the same as the display device 10 as described in conjunction with FIGS. 1 and 2, description of the first display device 10_2 and the second display device 10_3 may not be provided.

The first optical member 1510 may be located or provided between the first display device 10_2 and the first eyepiece 1210. The second optical member 1520 may be located or provided between the second display device 10_3 and the second eyepiece 1220. Each of the first optical member 1510 and the second optical member 1520 may include at least one convex lens.

The middle frame 1400 may be located or provided between the first display device 10_2 and the control circuit board 1600 and between the second display device 10_3 and the control circuit board 1600. The middle frame 1400 may serve to support and fix the first display device 102, the second display device 10_3, and the control circuit board 1600.

The control circuit board 1600 may be located or provided between the middle frame 1400 and the display device housing 1100. The control circuit board 1600 may be connected to the first display device 10_2 and the second display device 10_3 through the connector. The control circuit board 1600 may convert an image source inputted from the outside into the digital video data DATA and transmit the digital video data DATA to the first display device 10_2 and the second display device 10_3 through the connector.

The control circuit board 1600 may transmit the digital video data DATA corresponding to a left-eye image optimized for the user's left eye to the first display device 10_2 and may transmit the digital video data DATA corresponding to a right-eye image optimized for the user's right eye to the second display device 10_3. In one or more embodiments, the control circuit board 1600 may transmit substantially the same digital video data DATA to the first display device 10_2 and the second display device 103.

The display device housing 1100 may serve to accommodate the first display device 10_2, the second display device 10_3, the middle frame 1400, the first optical member 1510, the second optical member 1520, and the control circuit board 1600. The housing cover 1200 may be located or provided to cover one open surface of the display device housing 1100. The housing cover 1200 may include the first eyepiece 1210 at which the user's left eye is located or provided and the second eyepiece 1220 at which the user's right eye is located or provided. FIGS. 18 and 19 illustrate that the first eyepiece 1210 and the second eyepiece 1220 are located or provided separately, but embodiments of the present disclosure are not limited thereto. The first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. Therefore, the user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

The head mounted band 1300 may serve to secure the display device housing 1100 to the user's head such that the first eyepiece 1210 and the second eyepiece 1220 of the housing cover 1200 remain located or provided on the user's left and right eyes, respectively. If (e.g., when) the display device housing 1200 is implemented to be lightweight and compact, the head mounted display 1000 may be provided with, as illustrated in FIG. 20, an eyeglass frame instead of the head mounted band 1300.

In one or more embodiments, the head mounted display 1000 may further include a battery to supply power, an external memory slot to accommodate an external memory, and an external connection port and a wireless communication module to receive an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

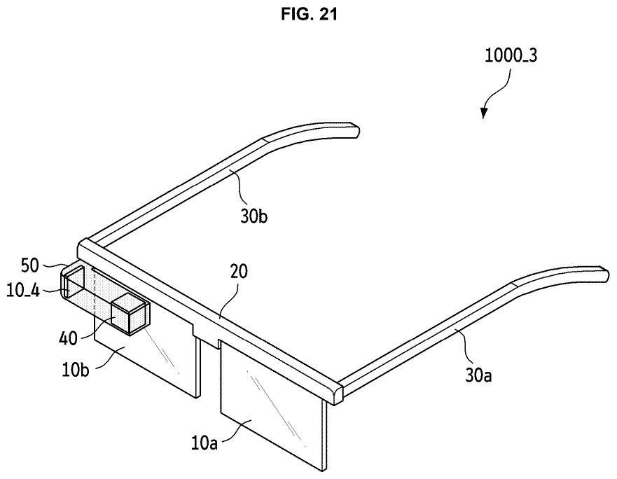

FIG. 21 illustrates a virtual reality device including a display device according to one or more embodiments. FIG. 21 illustrates a virtual reality device 1000_3 to which a display device 10_4 according to one or more embodiments is applied.

Referring to FIG. 21, the virtual reality device 1000_3 according to one or more embodiments may be a glasses-type or kind device. The virtual reality device 1000_3 according to one or more embodiments may include the display device 10_4, a left eye lens 10a, a right eye lens 10b, a support frame 20, temples 30a and 30b, a reflection member 40, and a display device housing 50.

FIG. 21 illustrates that the virtual reality device 1000_3 is a glasses-type or kind display device including the temples 30a and 30b. For example, the virtual reality device 1000_3 according to one or more embodiments is not limited to that as illustrated in FIG. 21 and may be applied in one or more suitable forms to one or more suitable electronic devices.

The display device housing 50 may include the display device 10_4 and the reflection member 40. An image displayed on the display device 10_4 may be reflected by the reflection member 40 and provided to the user's right eye through the right eye lens 10b. As a result, the user may view a virtual reality image displayed on the display device 10_4 with the right eye.

Although FIG. 21 illustrates that the display device housing 50 is located or provided at the right end of the support frame 20, embodiments of the present disclosure are not limited thereto. For example, the display device housing 50 may be located or provided at the left end of the support frame 20, and in this case, the image displayed on the display device 10_4 may be reflected by the reflection member 40 and provided to a user's left eye through the left eye lens 10a. As a result, the user may view a virtual reality image displayed on the display device 10_4 with the left eye. In one or more embodiments, the display device housing 50 may be located or provided at both (e.g., simultaneously) the left end and the right end of the support frame 20. In that case, the user may view the virtual reality image displayed on the display device 10_4 through both (e.g., simultaneously) the left eye and the right eye.

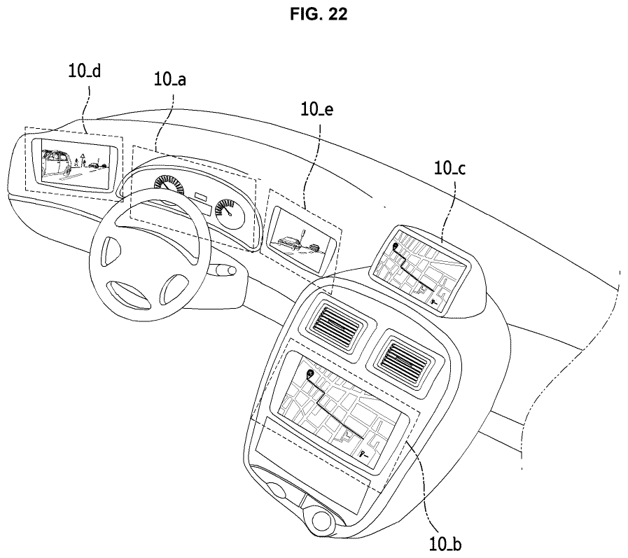

FIG. 22 illustrates a dashboard of an automobile and a center fascia including display devices according to one or more embodiments. FIG. 22 illustrates a vehicle to which display devices 10_a, 10_b, 10_c, 10_d, and 10_e according to one or more embodiments are applied.

Referring to FIG. 22, the display devices 10_a, 10_b, and 10_c according to one or more embodiments may be applied to the dashboard of the automobile, the center fascia of the automobile, or the center information display (CID) of the dashboard of the automobile. Further, the display devices 10_d, and 10_e according to one or more embodiments may be applied to a room mirror display instead of side mirrors of the automobile.

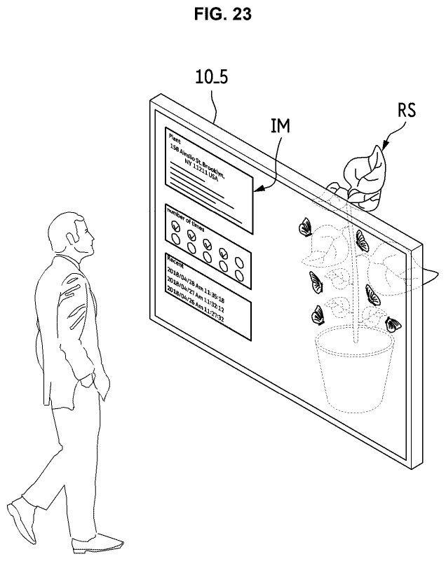

FIG. 23 illustrates a transparent (e.g., substantially transparent) display device including a display device according to one or more embodiments.

Referring to FIG. 23, a display device 10_5 according to one or more embodiments may be applied to the transparent display device. The transparent display device may display an image IM and also may transmit light. Thus, a user located or provided on the front side of the transparent display device may view an object RS or a background on the rear side of the transparent display device as well as the image IM displayed on the display device 105. If (e.g., when) the display device 10_5 is applied to the transparent display device, the substrate of the display device 10_5 may include a light transmitting portion capable of transmitting light or may include a material capable of transmitting light.

Although one or more embodiments of the present disclosure have been described with reference to the accompanying drawings, it will be apparent to those skilled in the art that the present disclosure can be embodied in one or more suitable forms without departing from the spirit and scope of the present disclosure. Thus, the embodiments as described herein are to be considered in all respects as illustrative and not restrictive.

What is claimed is:

1. An organic film composition for adhesion, comprising a monomer represented by Chemical Formula 1; a reactive unsaturated compound represented by Chemical Formula 2; a photoinitiator; and a solvent,
the monomer represented by Chemical Formula 1 being 25 parts to 50 parts by weight;
the reactive unsaturated compound represented by Chemical Formula 2 being 5 parts to 10 parts by weight;
the photoinitiator being 0.25 parts to 5 parts by weight; and
the solvent being 40 parts to 70 parts by weight,
based on 100 parts by weight of the organic film composition for adhesion: 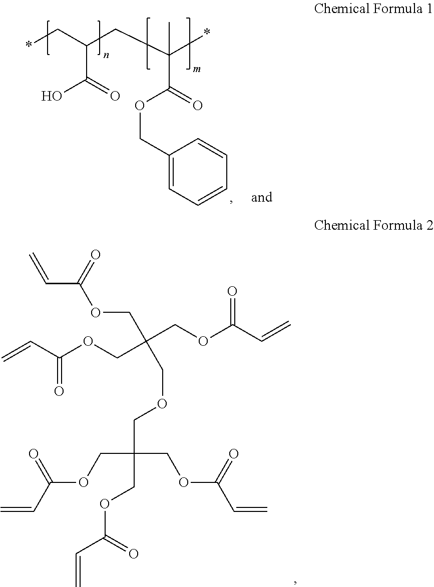
where n and m are integers.

2. The organic film composition as claimed in claim 1, wherein R_{C═C/C═O} of Equation 1 is 0.28 or more:
$${R}_{C = C / C = O} = {I}_{C = C} / {I}_{C = O} \qquad Equation 1$$
where the I_{C═C} is a C═C bond peak intensity in an infrared spectral spectrum, and the I_{C═O} is a C═O bond peak intensity in the infrared spectral spectrum.

3. The organic film composition as claimed in claim 1, wherein an adhesion force of the organic film composition for adhesion is equal to or greater than 2.2 mN.

4. The organic film composition as claimed in claim 1, wherein a modulus of the organic film composition for adhesion is equal to or less than 1.5 GPa.

5. The organic film composition as claimed in claim 1, wherein a bonding rate of the organic film composition for adhesion is 99.99% or higher at a temperature of 40° C. or higher.

6. A display device comprising:
a substrate;
an organic film on the substrate; and
a light emitting element on the organic film,
wherein the organic film comprises a monomer represented by Chemical Formula 1; a reactive unsaturated compound; a photoinitiator; and a solvent,
the monomer represented by the Chemical Formula 1 being 25 parts to 50 parts by weight;
the reactive unsaturated compound being 5 parts to 10 parts by weight;
the photoinitiator being 0.25 parts to 5 parts by weight; and
the solvent being 40 parts to 70 parts by weight,
based on 100 parts by weight of the organic film: 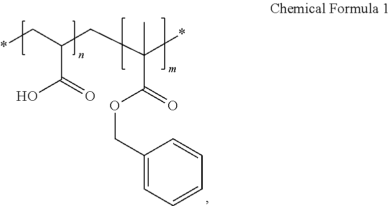
where n and m are integers.

7. The display device as claimed in claim 6, wherein the reactive unsaturated compound comprises a compound represented by Chemical Formula 2:

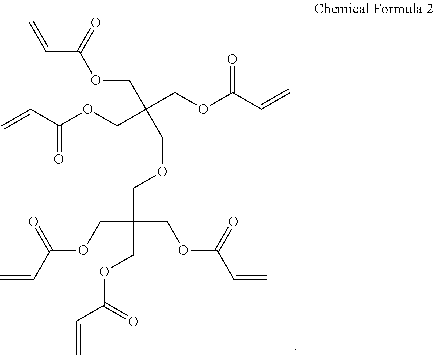 [SMILES: C=CC(=O)OCC(COCC(COC(=O)C=C)(COC(=O)C=C)COC(=O)C=C)(COC(=O)C=C)COC(=O)C=C]

8. The display device as claimed in claim 6, wherein, in the organic film, R_{C═C/C═O} of Equation 1 is 0.28 or more:
$${R}_{C = C / C = O} = {I}_{C = C} / {I}_{C = O} \qquad Equation 1$$
where the I_{C═C} is a C═C bond peak intensity in an infrared spectral spectrum, and the I_{C═O} is a C═O bond peak intensity in the infrared spectral spectrum.

9. The display device as claimed in claim 6, wherein an adhesion force of the organic film is equal to or greater than 2.2 mN.

10. The display device as claimed in claim 6, wherein a modulus of the organic film is equal to or less than 1.5 GPa.

11. The display device as claimed in claim 6, wherein a bonding rate of the organic film is 99.99% or higher at a temperature of 40° C. or higher.

12. The display device as claimed in claim 6, wherein the photoinitiator comprises an oxime-based photoinitiator.

13. The display device as claimed in claim 6, wherein the organic film further comprises an ionic initiator.

14. The display device as claimed in claim 6, wherein the light emitting element comprises:
a semiconductor stack;
a protective film on a side surface of the semiconductor stack; and
a contact electrode on the protective film,
wherein a part of the side surface of the semiconductor stack is exposed without being covered by the contact electrode, and the contact electrode is spaced from a top surface of the semiconductor stack.

15. The display device as claimed in claim 6, wherein the light emitting element comprises:
a semiconductor stack;
a conductive layer between the organic film and the semiconductor stack;
a protective film on side surfaces of the conductive layer and side surfaces of the semiconductor stack;
a first contact electrode provided on the protective film and connected to a conductive layer exposed without being covered by the protective film; and
a second contact electrode provided on the protective film and provided in a hole penetrating the conductive layer and a part of the semiconductor stack,
wherein each of the first contact electrode and the second contact electrode is spaced from a top surface of the semiconductor stack.

16. An electronic device comprising:
a display module to provide an image; and
a processor to transmit an image data signal to the display module,
wherein the display module comprises:
a substrate;
an organic film on the substrate; and
a light emitting element on the organic film,
wherein the organic film comprises a monomer represented by Chemical Formula 1; a reactive unsaturated compound; a photoinitiator; and a solvent,
the monomer represented by Chemical Formula 1 being 25 parts to 50 parts by weight;
the reactive unsaturated compound being 5 parts to 10 parts by weight;
the photoinitiator being 0.25 parts to 5 parts by weight; and
the solvent being 40 parts to 70 parts by weight of,
based on 100 parts by weight of the organic film: 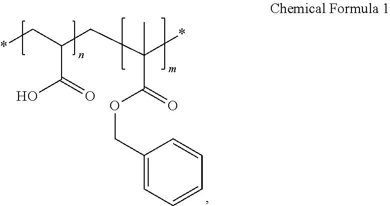
where n and m are integers.

17. The electronic device as claimed in claim 16, wherein the reactive unsaturated compound comprises a compound represented by Chemical Formula 2:

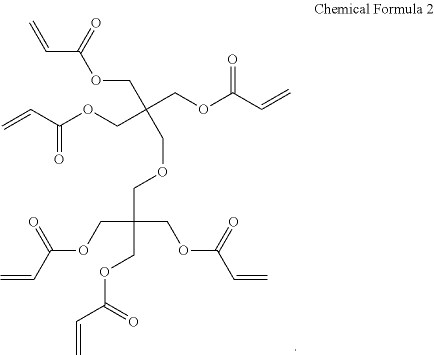 [SMILES: C=CC(=O)OCC(COCC(COC(=O)C=C)(COC(=O)C=C)COC(=O)C=C)(COC(=O)C=C)COC(=O)C=C]

18. The electronic device as claimed in claim 16, wherein, in the organic film, R_{C═C/C═O} of Equation 1 is 0.28 or more:
$${R}_{C = C / C = O} = {I}_{C = C} / {I}_{C = O} \qquad Equation 1$$
where the I_{C═C} is a C═C bond peak intensity in an infrared spectral spectrum, and the I_{C═O} is a C═O bond peak intensity in the infrared spectral spectrum.

19. The electronic device as claimed in claim 16, wherein an adhesion force of the organic film is equal to or greater than 2.2 mN.

20. The electronic device as claimed in claim 16, wherein a modulus of the organic film is equal to or less than 1.5 GPa.
